(19) United States
(12) Patent Application Publication
(10) Pub. No.: US 2025/0275079 A1
(43) Pub. Date: Aug. 28, 2025

(54) DISAGGREGATED SERVER ARCHITECTURE

(71) Applicant: NVIDIA CORPORATION, Santa Clara, CA (US)

(72) Inventors: Elad MENTOVICH, Tel Aviv (IL); Ryan ALBRIGHT, Beaverton, OR (US); Ryan WELLS, Raleigh, NC (US); Lisa YU, Cupertino, CA (US); James Stephen FIELDS, JR., Sante Fe, NM (US); James Bernard DALEY, San Jose, CA (US); Rama DARBHA, Durham, NC (US); Barak GAFNI, Sunnyvale, CA (US); Nick WHIDDEN, San Jose, CA (US)

(21) Appl. No.: 19/062,781

(22) Filed: Feb. 25, 2025

Related U.S. Application Data
(60) Provisional application No. 63/557,620, filed on Feb. 26, 2024.
(60) Provisional application No. 63/557,624, filed on Feb. 26, 2024.
(60) Provisional application No. 63/557,630, filed on Feb. 26, 2024.
(60) Provisional application No. 63/557,634, filed on Feb. 26, 2024.

(51) Int. Cl. H05K 7/14; G06F 1/18; H05K 7/20

(52) U.S. Cl. CPC H05K 7/1487; G06F 1/183; H05K 7/20727

(57) ABSTRACT

Systems, devices, and methods for disaggregating networking components are provided. An example networking chassis includes a first disaggregated server device supported by the networking chassis that includes a first central processing unit (CPU) and a first graphics processing unit (GPU) coupled with the first CPU. The networking chassis further includes a first insertable switch module communicably coupled with the first disaggregated server device that includes first switching chipsets and a first fabric management controller coupled with the first switching chipsets. The first insertable switch module at least partially controls data transmission associated with the first disaggregated server device. The first GPU of the first disaggregated server device is isolated on the first disaggregated server device, supported on the first disaggregated server device in the absence of other GPUs, or is otherwise the only GPU on the first disaggregated server device so as to provide modularity in networking applications.

### CROSS-REFERENCE TO RELATED APPLICATIONS

The present application claims priority to U.S. Provisional Patent Application No. 63/557,620, filed Feb. 26, 2024, U.S. Provisional Patent Application No. 63/557,624, filed Feb. 26, 2024, U.S. Provisional Patent Application No. 63/557,630, filed Feb. 26, 2024, U.S. Provisional Patent Application No. 63/557,634, Feb. 26, 2024, the entire contents of which applications are incorporated by reference in their entirety.

### TECHNOLOGICAL FIELD

Example embodiments of the present disclosure relate generally to network implementations and, more particularly, to disaggregating networking components to provide modularity in networking applications.

### BACKGROUND

Datacenters, high performance computing clusters, and/or the like are often formed of various computing components or networked devices (e.g., central processing units (CPUs), graphics processing units (GPUs), data processing units (DPUs), hosts, servers, racks, switches, etc.). Communication networks formed of electrical and/or optical devices (e.g., modules, transceivers, switches, and/or the like) may be used to enable communication between the networked devices forming these implementations. Through applied effort, ingenuity, and innovation, many of the problems associated with conventional networking and computing systems have been solved by developing solutions that are included in embodiments of the present disclosure, many examples of which are described in detail herein.

### BRIEF DESCRIPTION

Systems, devices, and methods are disclosed herein for providing disaggregated networking components. With reference to an example a networking chassis, the networking chassis may include a first disaggregated server device supported by the networking chassis. The first disaggregated server device may include a first central processing unit (CPU) and a first graphics processing unit (GPU) coupled with the first CPU. The first CPU and the first GPU may be configured to perform one or more computing operations associated with the networking chassis. The networking chassis may further include a first insertable switch module communicably coupled with the first disaggregated server device. The first disaggregated server device may include one or more first switching chipsets and a first fabric management controller operably coupled with the one or more first switching chipsets. The first insertable switch module may be configured to at least partially control data transmission associated with the first disaggregated server device.

In some embodiments, the first GPU of the first disaggregated server device may be isolated on the first disaggregated server device.

In some embodiments, the first GPU may be the only GPU on the first disaggregated server device.

In some embodiments, the first GPU may be supported on the first disaggregated server device in the absence of other GPUs on the first disaggregated server device.

In some embodiments, the first disaggregated server device further may include one or more first thermal management components.

In some further embodiments, the one or more first thermal management components may be configured to independently dissipate heat generated by the first CPU and/or the first GPU.

In some embodiments, the one or more first thermal management components may include one or more fans configured to dissipate heat generated by the first CPU and/or the first GPU.

In some embodiments, the first insertable switch module may further include one or more first switch thermal management components.

In some further embodiments, the one or more first switch thermal management components may be configured to independently dissipate heat generated by the one or more first switching chipsets and/or the first fabric management controller.

In some further embodiments, the one or more first thermal management components may include one or more fans configured to dissipate heat generated by the one or more first switching chipsets and/or the first fabric management controller.

In some embodiments, the first disaggregated server device and/or the first insertable switch module may be removably attached with the networking chassis.

In some embodiments, the networking chassis may further include one or more power supply units (PSUs) configured to provide a direct current (DC) power input to the first disaggregated server device and/or the first insertable switch module.

In some embodiments, the networking chassis may further include a second disaggregated server device. In such an embodiment the second disaggregated server device may include a second central processing unit (CPU) and a second graphics processing unit (GPU) coupled with the second CPU. The second CPU and second GPU may be configured to perform the one or more computing operations associated with the networking chassis.

In some further embodiments, the second GPU of the second disaggregated server device may be isolated on the second disaggregated server device.

In some further embodiments, the second GPU may be the only GPU on the second disaggregated server device.

In some further embodiments, the second GPU may be supported on the second disaggregated server device in the absence of other GPUs on the second disaggregated server device.

In some further embodiments, the first GPU of the first disaggregated server device and the second GPU of the second disaggregated server device may be communicably coupled via the first insertable switch module.

In some further embodiments, the first disaggregated server device and the second disaggregated server device may be removably attached with the networking chassis.

In some further embodiments, operation of the second disaggregated server device may be unimpacted by the removal of the first disaggregated server device.

In some embodiments, the networking chassis may further include a plurality of disaggregated server devices comprising the first disaggregated server device and a plurality of insertable switch modules comprising the first insertable switch module.

In some further embodiments, each of the plurality of disaggregated server devices and the plurality of insertable switch module may be physically supported by the networking chassis.

Systems, devices, and methods are further disclosed herein for providing disaggregated networking components in datacenter racks. An example, datacenter rack may include a first networking chassis including a first disaggregated server device supported by the first networking chassis. The first disaggregated server device may include a first CPU and a first GPU coupled with the first CPU. The first CPU and the first GPU may be configured to perform one or more computing operations associated with at least the first networking chassis. The datacenter rack may further include a second networking chassis including a second disaggregated server device supported by the second networking chassis. The second disaggregated server device may include a second CPU and a second GPU coupled with the second CPU. The second CPU and the second GPU may be configured to perform one or more computing operations associated with at least the second networking chassis.

In some embodiments, the first GPU of the first disaggregated server device may be isolated on the first disaggregated server device, and/or the second GPU of the second disaggregated server device may be isolated on the second disaggregated server device.

In some embodiments, the first GPU may be the only GPU on the first disaggregated server device, and/or the second GPU may be the only GPU on the second disaggregated server device.

In some embodiments, the first GPU may be supported on the first disaggregated server device in the absence of other GPUs on the first disaggregated server device, and/or the second GPU may be supported on the second disaggregated server device in the absence of other GPUs on the second disaggregated server device.

In some embodiments, the first disaggregated server device may further include one or more first thermal management components configured to independently dissipate heat generated by the first CPU and/or the first GPU.

In some further embodiments, the second disaggregated server device may further include one or more second thermal management components configured to independently dissipate heat generated by the second CPU and/or the second GPU.

In some further embodiments, the first disaggregated server device may be removably attached with the first networking chassis, and/or the second disaggregated server device may be removably attached with the second networking chassis.

In some further embodiments, operation of the second disaggregated server device may be unimpacted by the removal of the first disaggregated server device.

In some embodiments, the datacenter rack may further include one or more power supply units (PSUs) configured to provide a direct current (DC) power input to the first disaggregated server device and/or the second disaggregated server device.

In some embodiments, the first networking chassis further includes a first insertable switch module communicably coupled with the first disaggregated server device. The first insertable switch module may further include one or more first switching chipsets, and a first fabric management controller operably coupled with the one or more first switching chipsets. The first insertable switch module may be configured to at least partially control data transmission associated with the first disaggregated server device.

In some further embodiments, the first insertable switch module may further include one or more first switch thermal management components configured to independently dissipate heat generated by the one or more first switching chipsets and/or the first fabric management controller.

In some further embodiments, the second networking chassis further includes a second insertable switch module communicably coupled with the second disaggregated server device. The second insertable switch module may further include one or more second switching chipsets and a second fabric management controller operably coupled with the one or more second switching chipsets. The second insertable switch module may be configured to at least partially control data transmission associated with the second disaggregated server device.

In some further embodiments, the first insertable switch module may be communicably coupled with the second insertable switch module.

In some embodiments, the first networking chassis may further include a plurality of insertable switch modules including the first insertable switch module.

In some further embodiments, the second networking chassis may further include a plurality of insertable switch modules including the second insertable switch module.

In some embodiments, the first networking chassis may further include a plurality of disaggregated server devices including the first disaggregated server device.

In some further embodiments, a respective GPU of each of the disaggregated server devices of the first networking chassis may supported on the respective disaggregated server device in the absence of other GPUs on the respective disaggregated server device.

In some embodiments, the second networking chassis may further include a plurality of disaggregated server devices including the second disaggregated server device.

In some further embodiments, a respective GPU of each of the disaggregated server devices of the second networking chassis may be supported on the respective disaggregated server device in the absence of other GPUs on the respective disaggregated server device.

In some further embodiments, the first insertable switch module may be removably supported by the first networking chassis, and/or the second insertable switch module may be removably supported by the second networking chassis.

Systems, devices, and methods are further disclosed herein for providing disaggregated networking components in networking systems (e.g., connected networked domains). An example networking system may include a first network domain including at least a first networking chassis. The first networking chassis may include a first disaggregated server device supported by the first networking chassis. The first disaggregated server device may include a first central processing unit (CPU) and a first graphics processing unit (GPU) coupled with the first CPU. The first CPU and the first GPU may be configured to perform one or more computing operations associated with the first networking chassis. The networking system may further include a second network domain including a plurality of rack switches operably coupled with at least the first networking chassis.

In some embodiments, the first GPU of the first disaggregated server device may be isolated on the first disaggregated server device.

In some embodiments, the first GPU may be the only GPU on the first disaggregated server device.

In some embodiments, the first GPU may be supported on the first disaggregated server device in the absence of other GPUs on the first disaggregated server device.

In some embodiments, the first networking chassis may further include a first insertable switch module operably coupled with the first disaggregated server device. The first insertable switch module may include one or more first switching chipsets and a first fabric management controller operably coupled with the one or more first switching chipsets. The first insertable switch module may be configured to at least partially control data transmission associated with the first disaggregated server device.

In some further embodiments, the first insertable switch module may be operably coupled with at least one of the plurality of rack switches forming the second network domain.

In some embodiments, the first network domain and the second network domain are operably coupled via one or more optical transceivers and optical communication mediums.

In some embodiments, a least one of the plurality of rack switches includes one or more switching chipsets and a fabric management controller operably coupled with the one or more switching chipsets.

In some embodiments, each of the plurality of rack switches of the second network domain may be operably coupled with the first networking chassis.

In some embodiments, the first network domain includes a plurality of networking chassis including the first networking chassis and each of the plurality of rack switches may be operably coupled with each of the plurality of networking chassis.

In some embodiments, the first network domain includes a plurality of datacenter racks where a first datacenter rack includes at least the first networking chassis.

Systems, devices, and methods are further disclosed herein for cable cartridges for establishing connections between disaggregated server devices. An example cable cartridge for network connections may include a housing defining a first portion configured to be coupled with at least a first disaggregated server device supported by a networking chassis. The first disaggregated server device may include a first central processing unit (CPU); and a first graphics processing unit (GPU) coupled with the first CPU, wherein the first CPU and the first GPU may be configured to perform one or more computing operations associated with the networking chassis. The housing may further include a second portion configured to be coupled with at least a first insertable switch module supported by the networking chassis. The cable cartridge may be configured to operably couple the first disaggregated server device and the first insertable switch module.

In some embodiments, the first GPU of the first disaggregated server device may be isolated on the first disaggregated server device.

In some embodiments, the first GPU may be the only GPU on the first disaggregated server device.

In some embodiments, the first GPU may be supported on the first disaggregated server device in the absence of other GPUs on the first disaggregated server device.

In some embodiments, the first portion of the housing may configured to be operably coupled with a plurality of disaggregated server devices including the first disaggregated server device.

In some further embodiments, the cable cartridge may be configured to operably couple the plurality of disaggregated server devices with the first insertable switch module.

In some embodiments, the first insertable switch module may further include one or more first switching chipsets a first fabric management controller operably coupled with the one or more first switching chipsets. The first insertable switch module may be configured to at least partially control data transmission associated with the first disaggregated server device.

In some embodiments, the second portion of the housing may be configured to be operably coupled with a plurality of insertable switch modules including the first insertable switch module.

In some further embodiments, the cable cartridge may be configured to operably coupled the plurality of insertable switch modules with at least the first disaggregated server device.

In some embodiments, the first disaggregated server device and/or the first insertable switch module may be removably attached with the housing.

In some embodiments, at least the first portion may include an attachment mechanism for removably attaching at least the first portion of the housing with the first disaggregated server device.

In some further embodiments, the attachment mechanism may further include a float frame configured to receive a connector of the first disaggregated server device therein.

In some further embodiments, the float frame may be configured to enable movement of the connector within the attachment mechanism in at least a first direction relative to the float frame.

In some further embodiments, the float frame may be configured to enable movement of the connector within the attachment mechanism in a second direction substantially perpendicular to the first direction.

In some still further embodiments, the float frame may include a load control device configured to maintain connection between the first disaggregated server device and the cable cartridge.

In some further embodiments, the load control device may include at least a first spring configured to urge the attachment mechanism in a third direction that is substantially perpendicular to the first direction and the second direction.

Methods for network sequencing/initialization for disaggregated server devices are also provided. An example method for network sequencing may include providing a cable cartridge including a housing defining a first portion and a second portion. The method may further include coupling the first portion of the housing with at least a first disaggregated server device supported by a networking chassis as described herein. The method may further include coupling the second portion with at least a first insertable switch module supported by the networking chassis and the cable cartridge may be configured to operably couple the first disaggregated server device and the first insertable switch module.

In some embodiments, the method may further include determining, via an identification operation, one or more device characteristics of the first disaggregated server device in response to connection between the first disaggregated server device and the cable cartridge.

In some embodiments, the method may further include first powering one or more rack switches operably coupled with the first networking chassis, second powering the first insertable switch module, and third powering the first disaggregated server device.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having described certain example embodiments of the present disclosure in general terms above, reference will now be made to the accompanying drawings. The components illustrated in the figures may or may not be present in certain embodiments described herein. Some embodiments may include fewer (or more) components than those shown in the figures.

FIG. 1 illustrates a schematic diagram of an example datacenter network architecture (e.g., a networking system) in accordance with one or more embodiments of the present disclosure;

FIG. 2 illustrates a schematic diagram of an example server system architecture, such as used in the datacenter network architecture of FIG. 1 in accordance with one or more embodiments of the present disclosure;

FIGS. 3-4 illustrate example networking system configurations in accordance with one or more embodiments of the present disclosure;

FIG. 5 illustrates an example optical transceiver for operably coupling network components in accordance with one or more embodiments of the present disclosure;

FIG. 6 illustrates an example Mid-Board Optical Modules (MBOM) and/or Co-Packaged Optics (CPO) implementation for operably coupling network components in accordance with one or more embodiments of the present disclosure;

FIG. 7 illustrates a plurality of datacenter racks in accordance with one or more embodiments of the present disclosure;

FIG. 8 illustrates an example datacenter rack in accordance with one or more embodiments of the present disclosure;

FIGS. 9A-9B illustrate an example networking chassis in accordance with one or more embodiments of the present disclosure;

FIGS. 10A-10B illustrate an example disaggregated server device in accordance with one or more embodiments of the present disclosure;

FIGS. 10A-10B illustrate an example disaggregated server device in accordance with one or more embodiments of the present disclosure;

FIGS. 11A-11B illustrate an example CPU and GPU implementation of an example disaggregated server device in accordance with one or more embodiments of the present disclosure;

FIG. 12 illustrates a schematic diagram of example circuitry, such as of an example CPU and GPU in accordance with one or more embodiments of the present disclosure;

FIG. 13 illustrates an example insertable switch module in accordance with one or more embodiments of the present disclosure;

FIG. 14 illustrates a schematic diagram of an example insertable switch module in accordance with one or more embodiments of the present disclosure;

FIG. 15 illustrates an example cable cartridge in accordance with one or more embodiments of the present disclosure;

FIGS. 16A-16C illustrate example attachment mechanism of the example cable cartridge of FIG. 15 in accordance with one or more embodiments of the present disclosure;

FIG. 17 illustrates an exploded view of the attachment mechanism of FIGS. 16A-16C in accordance with one or more embodiments of the present disclosure;

FIG. 18 illustrates a logical representation of a networking configuration in accordance with one or more embodiments of the present disclosure;

FIG. 19 illustrates an example method for connecting an example networking configuration in accordance with one or more embodiments of the present disclosure;

FIG. 20 illustrates an example method for network sequencing in accordance with one or more embodiments of the present disclosure;

FIG. 21 illustrates an example compute fabric in accordance with one or more embodiments of the present disclosure;

FIG. 22 illustrates an example logical architecture for storage and in-band fabric implementation in accordance with one or more embodiments of the present disclosure; and

FIG. 23 illustrates an example architecture for scale out storage in accordance with one or more embodiments of the present disclosure.

### DETAILED DESCRIPTION

### Overview

Various embodiments of the present disclosure will now be described more fully hereinafter with reference to the accompanying drawings in which some but not all embodiments are shown. Indeed, the present disclosure may be embodied in many different forms and should not be construed as limited to the embodiments set forth herein; rather these embodiments are provided so that this disclosure will satisfy applicable legal requirements. Like reference numerals refer to like elements throughout.

As described above, datacenters, high performance computing clusters, networking system and/or the like are often formed of various computing components or networked devices, and communication networks formed of electrical and/or optical devices may be used to enable communication between the networked devices forming these implementations. These network systems and architectures may be formed of disparate, linked network nodes that include processing components (e.g., CPUs, GPUs, etc.) as well as network communication components (e.g., communication hardware, fabric management components, etc.). These implementations may be used to complete high computational tasks or operations, such as the training of language models (LLMs) for text generation, content creation, and natural language understanding, the executing of algorithms and models designed for generative AI applications, large-scale models or high-dimensional data analysis, and/or the like.

As the computational burden associated with these operations increases, traditional network architectures rely on increasing the number of processing components supported by a particular node (e.g., increasing the processor density). By way of example, a conventional system may operate to maximize the number of CPUs and/or GPUs that are housed by a single server device in order to address the ever increasing computation burden associated with these operations. In order to support the increasing number of processing components, each server will similarly be required to increase the number of communication components to support the increased computational output. The increase in the number components on each server results in various computational and thermal density issues. For example, traditional systems with increased processing density per server are often incapable of sufficiently dissipating the heat generated by these components during operation resulting in an increased component failure rate. Furthermore by providing a plurality of computing components, such as GPUs, on a single server rack, the failure of one component (e.g., a particular GPU) requires maintenance and/or replacement of the entire server rack.

In order to solve these issues and others, the embodiments of the present disclosure provide disaggregated server devices that operate as a modular, scalable building block for large AI applications that eliminate or otherwise minimize the density concerns of conventional solutions. In particular, the networking chassis described herein that form a datacenter rack may include a disaggregate server device (e.g., a computing node in the example networking system) that includes only a single GPU as opposed to a plurality of GPUs on a single server device. Additionally, the network communication functionality (e.g., switching chipsets, fabric management controllers, etc.) of these networking chassis are supported by separate insertable switch modules (e.g., on separate devices from the GPUs and other computation hardware). By isolating the switching hardware and the computational hardware and providing single GPU server devices (e.g., the disaggregated server devices described hereinafter), the embodiments described herein may address the computational requirements of emerging computation operations (e.g., AI models and the like) without increasing the per server density. Furthermore, the disaggregated server devices described hereafter improve the maintenance, replaceability, modification, and usability of networking systems by enabling the ease of replacement of particular server devices while minimizing the impact to the operation of other server devices in the same networking chassis.

### Example Networking Systems

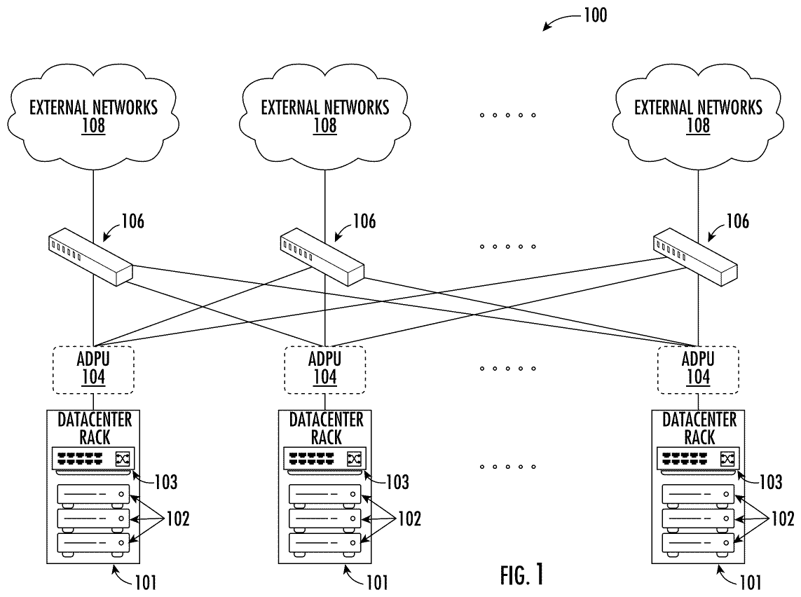

As shown in FIGS. 1-4, various networking systems for implementing the disaggregated server devices and architecture of the present disclosure are illustrated. With reference to FIG. 1, a schematic diagram of an example datacenter network architecture 100 is shown. As used herein, the terms “network architecture,” “networking environment,” “networking configuration,” “networking system,” “networking implementation,” and/or the like may be used interchangeably to refer to any combination of networking devices, computing device, communication devices, and/or the like without limitation. The present disclosure further contemplates that the configuration, arrangement, topology, etc. of the networking system may similarly vary based on the intended application of the networking system. Said differently, the disaggregated server devices, networking chassis, datacenter racks, and the like described herein may be applicable to any networking configuration without limitation.

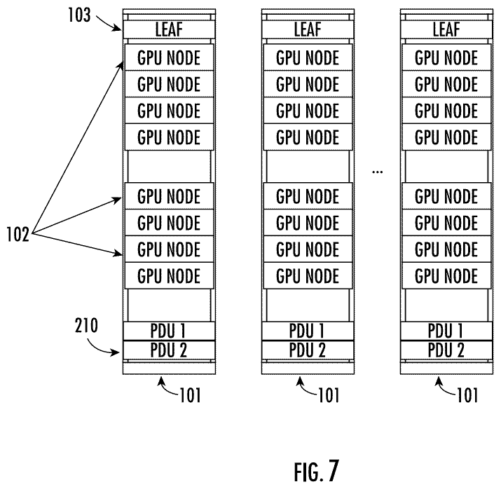

With continued reference to FIG. 1, the datacenter network architecture 100 (e.g., system 100) may include a plurality of datacenter racks 101 that may operate as the physical structure that supports or otherwise houses the computing devices, resources, etc. described herein. As described hereinafter with reference to FIG. 8, for example, an example datacenter rack 101 may include one or more networking chassis (e.g., first chassis 105 in FIG. 8) that represent a subset of the computing resources of the datacenter rack 101. Said differently, the datacenter rack 101 may include a networking chassis that includes a portion of interconnected computing resources (e.g., disaggregated server devices 102 and insertable switch modules 103) of the datacenter rack 101. The present disclosure contemplates that the datacenter rack 101 may include any configuration and may further be dimensioned (e.g., sized and shaped) based on the intended application of datacenter network architecture 100.

The example datacenter rack 101 may include disaggregated server devices 102 and insertable switch modules 103 supported therein, such as via the networking chassis described above. The system 100 may further include rack switches 106 that may operably couple the datacenter racks 101 to external networks 108 and or any other networking component. By way of example, the rack switches 106 may be communicably coupled with the insertable switch modules 103 of the datacenter rack 101. The disaggregated server devices 102 may be configured to house computing resources for performing the operations as described hereinafter with reference to FIGS. 8-14. The rack switches 106 may manage and route data between the datacenter racks, via the insertable switch modules 103, and the external networks 108. The external networks 108 may connect the datacenter network architecture 100 to external devices, services, or other datacenters, enabling communication beyond the system 100.

The datacenter racks 101 and associated networking chassis may include a plurality disaggregated server devices 102 that may house multiple servers, each containing various computing resources. As described above, in order to enable a modular implementation with minimized computation density concerns, the disaggregated server devices 102 may include an isolated or single GPU as described hereinafter. While maintaining this modularity, the computing resources of the disaggregated server device 102 may include central processing units (CPUs), such as NVIDIA Grace™ CPUs, and graphics processing units (GPUs), such as NVIDIA® H100 Tensor Core GPUs, Hopper™ GPUs, etc. The servers may also include memory, such as high-bandwidth memory (HBM) for GPUs, and storage devices, such as NVMe (Non-Volatile Memory Express) SSDs for fast data access. Each disaggregated service device 102 within the networking chassis of the datacenter rack 101 may be configured to handle specific types of workloads, such as general-purpose computing, data processing, specialized tasks like artificial intelligence (AI) and machine learning (ML) applications, and/or the like. For example, NVIDIA® Hopper™ GPUs may be used to accelerate AI and ML workloads by performing parallel processing of large datasets as part of AI and ML model training. The disaggregated server devices 102 may be connected to one or more rack switches 106, allowing the servers systems 102 to communicate with other systems within the datacenter or external networks 108. The configuration of the datacenter rack 101 may be scalable, such as by the inclusion of additional disaggregated server devices 102 with a single, isolated GPU per server device 102 based on computing requirements. The disaggregated server devices 102 of an example networking chassis (within a datacenter rack 101) may be interconnected or otherwise operably coupled, such as via optical communication techniques.

As described hereinafter, the disaggregated server devices 102 may also include insertable switch module(s) 103 that operate to manage and establish communication between the disaggregated server devices 102 of the datacenter rack 101 and components that are external to the particular datacenter rack 101. The insertable switch module(s) 103 may connect each disaggregated server devices 102 to the broader datacenter network, such as via high-speed networking protocols (e.g., Ethernet protocols, InfiniBand® protocols, etc.) The insertable switch module(s) 103 may reduce cable complexity by aggregating connections for each of the disaggregated server devices 102 within the datacenter rack 100 and then linking to higher-layer switches, such as rack switches 106, within the datacenter 100. Each insertable switch module 103 may be connected to every disaggregated server device 102 within the datacenter rack 100, such as through short cables, and the insertable switch module 103 may then uplink to the rack switches 106.

The insertable switch module(s) 103 in the networking chassis of the datacenter racks 101 may also support various network features such as VLAN segmentation, load balancing, and quality of service (QoS) management, ensuring optimized traffic flow within the rack and the datacenter 100 as a whole. In some configurations, the insertable switch module(s) 103 may offer redundancy by employing multiple uplinks to rack switches 106, providing fault tolerance in case of a switch or connection failure. Additionally or alternatively, the insertable switch module(s) 103 may be operatively coupled to the advanced datacenter processing units (ADPUs) 104, enabling efficient offloading of data processing and security tasks, further reducing the computational burden on the server CPUs and improving overall data flow within the rack. In other embodiments, the insertable switch modules 103 may include one or more advanced datacenter processing units (ADPUs) 104.

In some embodiments, the datacenter architecture 100 (e.g., system 100) may leverage one or more advanced datacenter processing units (ADPUs) 104 that may integrate network interface cards (NICs) and data processing unit (DPU) functionalities to enhance the efficiency of data center operations. The ADPU 104 may be configured to offload various network, storage, and security tasks from the disaggregated server devices 102 and/or the insertable switch modules 103, in particular, the CPUs and/or GPUs in the disaggregated server devices 102, allowing the CPUs and/or GPUs to focus on compute-intensive workloads. The ADPU 104 may facilitate high-speed data transmission, optimize data flow, and enable advanced network services with minimal impact on server performance. The NIC component within the ADPU 104 may handle standard network functions, such as packet transmission and reception, supporting high-speed Ethernet or InfiniBand® protocols. By facilitating fast data transfers between the disaggregated server devices 102 and external networks 108, the NIC enables efficient communication across the datacenter environment 100.

The NIC of the ADPU 104 may also support offloading network protocol processing, reducing the overhead on disaggregated server devices 102, in particular, CPUs and/or GPUs in the disaggregated server devices 102, and improving overall data throughput. The DPU component of the ADPU 104 may extend these capabilities by offloading more advanced processing tasks, such as data encryption and decryption, packet inspection and filtering, virtualization support, and/or the like. In some example embodiments, the ADPU 104 may be NVIDIA® BlueField®-2 DPUs that provide a high-performance platform for data center acceleration. The BlueField®-2 architecture may include up to 8 Arm cores, enabling the ADPU 104 to execute network, storage, and security tasks independently of the disaggregated server devices 102, in particular, CPUs in the disaggregated server devices 102. By performing these tasks closer to the data source, the ADPU 104 may reduce data movement across the network, lower latency, and enhance overall system efficiency.

The ADPU 104 may also include a dedicated memory subsystem, such as dynamic random-access memory (DRAM), to support local processing and ensure high-speed data access. Additionally, the ADPU 104 may be configured to manage NVMe over Fabrics (NVMe-oF) storage protocols, allowing for efficient remote storage access and fast data retrieval. The combined NIC and DPU functionalities within the ADPU 104 may support various advanced networking features, including traffic shaping and load balancing, remote direct memory access (RDMA), virtual machine and container isolation, and/or the like.

The rack switches 106 may manage the data flow between the datacenter racks 101, such as data to and from the disaggregated server devices 102 via the insertable switch modules 103, and the external networks 108. The rack switches 106 may be responsible for routing and distributing data between datacenter racks 101 within the datacenter 100 and facilitating communication with external networks 108. Rack switches 106 may be configured to support various high-speed network protocols, such as Ethernet or InfiniBand® protocols, depending on the performance and bandwidth requirements of the datacenter. The rack switches 106 may include optical switches, which use light signals for data transmission, offering high bandwidth and low latency for long-distance communication. Alternatively, the rack switches 106 may include electrical switches, which rely on electronic signals and may be used for shorter distances or when lower latency is a priority. In some configurations, hybrid switches may be used, combining both optical and electrical components to balance performance and flexibility. The rack switches 106 may be advanced networking switches, such as Nvidia® Quantum-2 switches, configured to provide high throughput capabilities. The rack switches 106 may operate at different layers of the network stack, including Layer 2 (data link layer) and Layer 3 (network layer), to perform switching and routing functions. Multiple rack switches 106 may be interconnected to provide redundancy and load balancing for reliable data transfer even if one switch fails. The rack switches 106 may support scalable configurations, allowing the network architecture to expand as additional disaggregated server devices 102 or external networks 108 are introduced.

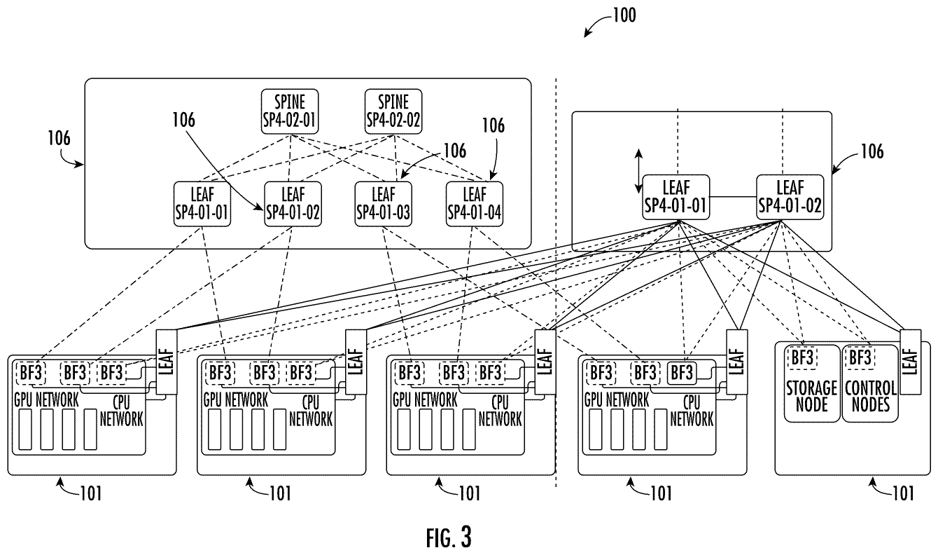

In some embodiments, the number and arrangement of rack switches 106 within the datacenter network architecture 100 may be based on the overall network topology deployed in the datacenter environment 100. Additional example network topologies are illustrated in FIGS. 3-4, 18, and 21-23 described hereafter. The choice of network topology may influence the scalability, performance, fault tolerance, and bandwidth distribution of the network, thus affecting how many switches are required and how they are interconnected. Non-limiting examples of network topology may include fat-tree topology, SlimFly topology, dragonfly topology, HyperX topology, torus topology, Clos (folded-Clos) topology, and/or the like. For instance, in a fat-tree topology, the network may be structured as a multi-tiered hierarchy with equal-cost paths between any two endpoints. The fat-tree topology may be built using three layers of switches: leaf switches at the bottom layer, directly connected to the disaggregated server devices 102 via the insertable switch modules 103, spine switches in the middle layer, which interconnect the leaf switches, and core switches at the top, which interconnect multiple sets of spine switches. In a SlimFly topology, the rack switches 106 may be arranged to minimize the average path length between servers, reducing communication latency. The total number of rack switches 106 may be fewer than in fat-tree topology, but their arrangement may be more complex to optimize the number of direct and indirect connections between nodes. Dragonfly topology may organize switches into groups (or “pods”), with high-bandwidth connections within each group and lower-bandwidth connections between groups. The rack switches 106 may be arranged into several pods, with each pod containing a set of leaf switches connected to insertable switch modules 103, disaggregated server devices 102, and local spine switches. In addition, there may be fewer inter-pod connections than intra-pod connections.

In hyperX topology, switches may be arranged in a multi-dimensional grid, with each switch connected to multiple neighboring switches in different dimensions. The total number of switches may scale with the number of dimensions and network size. In a torus topology, the rack switches 106 may be connected in a loop or ring structure. Torus topology may offer reduced wiring complexity and built-in redundancy, as each switch is connected to multiple adjacent switches. In larger datacenters, a higher-dimensional torus (e.g., 3D or 4D torus) may be implemented, where switches are arranged in a multi-layered grid. In a Clos topology, also known as a folded-Clos or CLOS architecture, the rack switches 106 may be arranged in multiple layers of switching stages, with each stage containing multiple switches. In this configuration, each disaggregated server device 102 and insertable switch module 103 may connect to a set of leaf switches, which in turn connect to multiple spine switches. Additional spine and leaf switches may be added as the network grows, with the number of rack switches 106 increasing in proportion to the number of datacenter racks and external networks connected.

The external networks 108 represent a range of connectivity options that facilitate communication between the datacenter and various external systems, such as other datacenters, cloud service providers, and/or the like. These external networks 108 may include local area networks (LANs), which connect devices within a limited geographical area, as well as WANs that span larger distances and connect multiple LANs. Additionally, external networks 108 may include cloud networks, which provide scalable resources and services hosted remotely, and private networks, which offer secure communication channels for sensitive data transfer. Other types of external networks may include virtual private networks (VPNs) that enable secure access over the internet and Content Delivery Networks (CDNs) that optimize the delivery of content to end-users. Each of these external networks may utilize various communication protocols, such as Ethernet, InfiniBand®, or MPLS (Multiprotocol Label Switching) protocols, to ensure reliable and efficient data transfer.

The description provided herein is merely an embodiment of the datacenter network architecture and the associated components, including the rack switches 106 and the ADPU 104. Various modifications, alterations, and adaptations may be made without departing from the scope of the disclosure. The specific configurations, components, and functionalities described are illustrative and may be replaced or modified in other embodiments depending on the particular requirements of the datacenter environment. For example, different network topologies, alternative processing units, or variations in server configurations may be used to achieve similar objectives. As such, the scope of the invention should not be limited by the described embodiment.

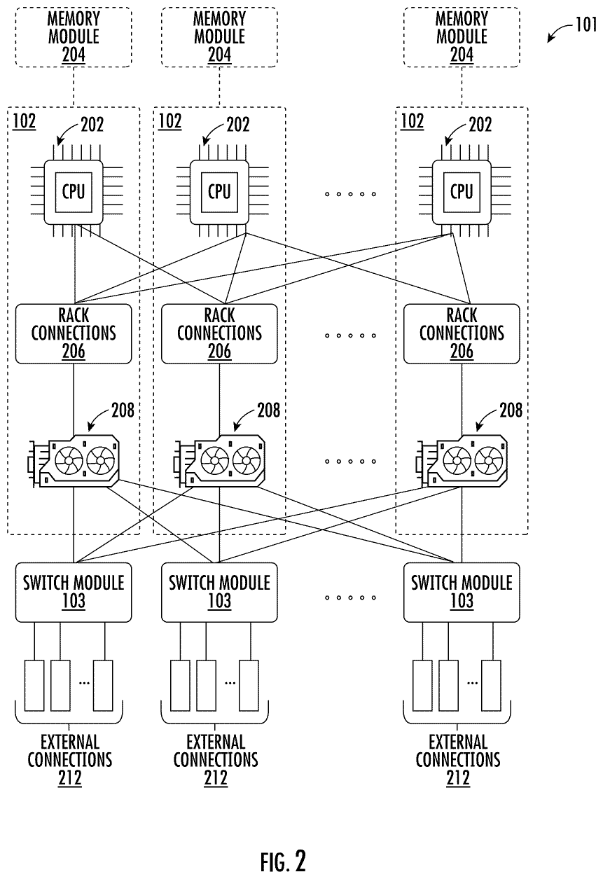

With reference to FIG. 2 a schematic diagram of an example datacenter rack 101, some or all of which may be included in datacenter architecture 100 of FIG. 1, is illustrated. The datacenter rack 101 may include a CPU 202 and GPUs 208 (e.g., as part of the disaggregated server devices 102), memory modules 204, rack connections 206, insertable switch modules 103, and/or external connections 212. As described hereinafter, the CPU 202, such as the individual CPUs supported by respective disaggregated server devices 102, may manage operations within the datacenter rack 101 and communicate with the other components. The memory modules 204 may provide fast access to data for the CPU 202 and/or GPU 208. The rack connections 206 may operably couple the various components of the datacenter rack 101, while the insertable switch module 103 may facilitate or at least partially control communication between the components datacenter rack (e.g., between respective disaggregated server devices 102) as well as between the datacenter rack 101 and the components of the system 100. The external connections 212 operably couple the datacenter rack 101, and the networking chassis forming the same, with external networks or other systems.

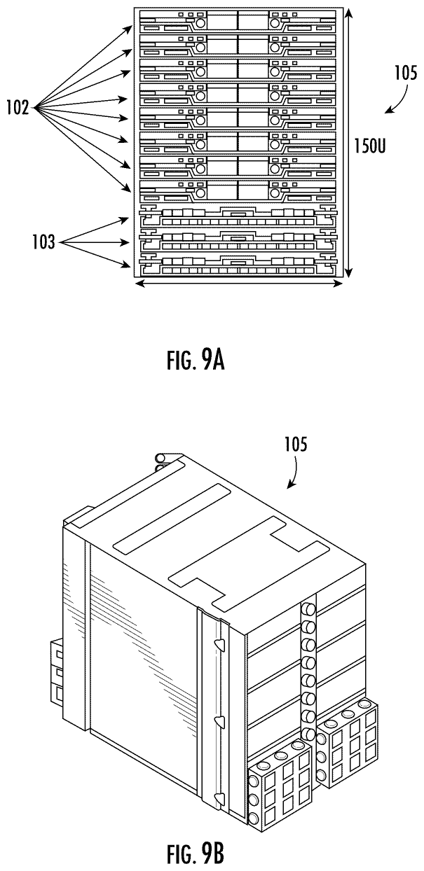

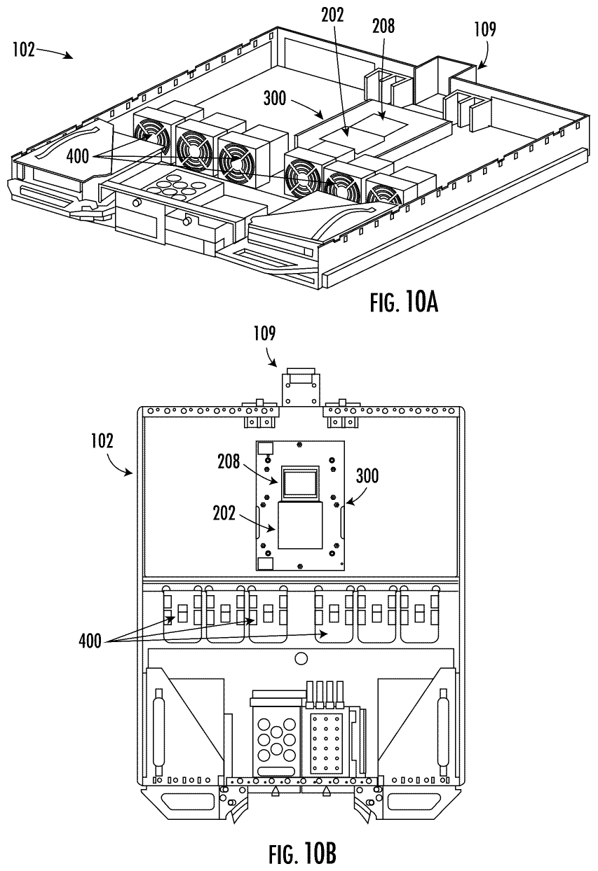

The CPU 202 may manage overall operations within a datacenter rack 101 (e.g., associated with a particular disaggregated server devices 102). The CPU 202 may execute instructions, process data, and control communication between the other components, including the memory module 204, rack connections 206, and GPUs 208. The CPU 202 may be connected to the memory module 204, providing fast access to data required for computational tasks. The CPU 202 may communicate with the GPUs 208, enabling the CPU 202 to offload specialized computing tasks such as graphics rendering, AI, and ML workloads, and/or the like. Additionally, the CPU 202 may manage external communication via external connections 212, facilitating data exchange between the disaggregated server devices 102 and external networks 108 or other systems. As described hereafter, a particular networking chassis of a datacenter rack 101 may include a plurality of CPUs 202 and/or GPUs 208 where each disaggregated server device 102 of the networking chassis includes only a single CPU 202 and GPU 208. The operations and functionality of the CPU 202 and the GPU 208 are described more fully hereinafter with reference to FIGS. 10A-12.

The memory module 204 may provide fast data access for the CPU 202, allowing the CPU to efficiently execute instructions and process data. The memory module 204 may include various types of memory, such as DRAM or high-bandwidth memory (HBM), depending on the specific performance requirements. The memory module 204 may be directly connected to the CPU 202 to minimize latency and enable high-speed data transfers between the memory and the CPU. The size and type of the memory module 204 may be scalable, allowing for adjustments based on the workload and data processing needs of the server system. Multiple memory modules that are the same or similar to the memory module 204 may be included in the architecture to support additional CPUs or to increase memory capacity as required by the computing tasks.

The rack connections 206 may facilitate communication between the CPU 202, GPUs 208, and other components within the disaggregated server devices 102. These rack connections 206 may be responsible for routing data between these components, ensuring efficient data flow and coordination during processing tasks. The rack connections 206 may include various types of technologies, such as Peripheral Component Interconnect Express (PCIe) switches, which connect the CPU to multiple GPUs, enabling high-speed data transfers, Ethernet switches for managing communication with external networks or InfiniBand® switches designed for low-latency, high-throughput data transfers between servers in a high-performance computing environment, and/or the like. The architecture of the rack connections 206 may be scalable, accommodating additional components as needed to meet increasing performance demands. Furthermore, the rack connections 206 may provide features such as load balancing and fault tolerance, which improve the reliability and efficiency of data transmission within the server system.

The insertable switch module 103 may facilitate or partially control communication between the components (e.g., a single CPU 202 and a single GPU 208) of the disaggregated server devices 102. For example, the insertable switch module 103 may be configured to enable high-speed data transfer and coordination for parallel processing tasks. The insertable switch module 103 may include switching chipsets, fabric management controllers, and/or other communication hardware that may be traditionally supported by the server device (e.g., as part of the CPU and GPU configuration). In other words, the embodiments of the present disclosure may provide networking chassis of datacenter racks 101 with communication hardware isolated or otherwise separated from the computing hardware of the disaggregated server device 102. In doing so, the insertable switch module 103 operates as a modularly replaceable component within the datacenters rack 101 that may be replaced without impact to (e.g., without removal of) the disaggregated server device(s) 102. The components of the insertable switch module 103 may include various types of interconnect technologies, such as NVIDIA® NVSwitches (e.g., NVLink® switches) or other high-performance fabric switches, depending on the system configuration. In some configurations, the insertable switch module 103 may support hybrid or optical interconnect technologies to enhance performance based on system requirements.

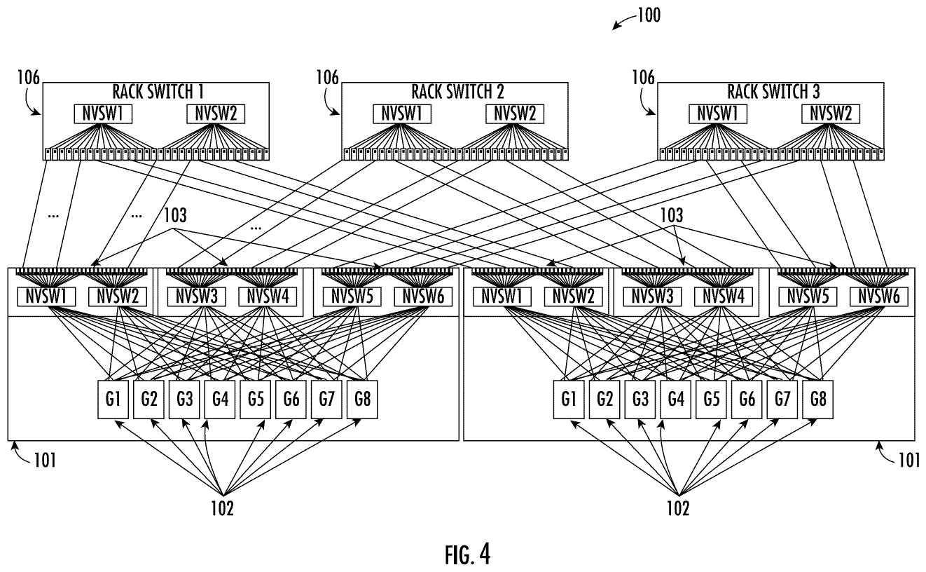

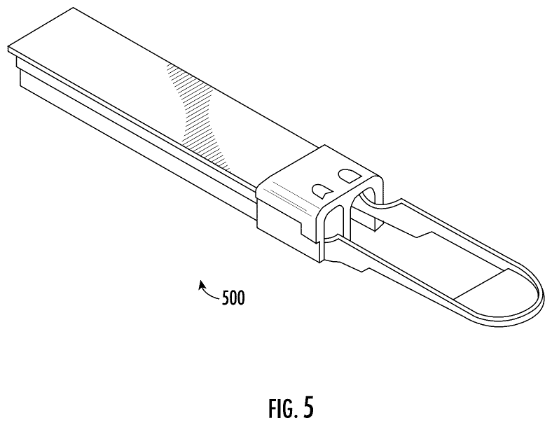

The external connections 212 may provide interfaces between the disaggregated server devices 102 and external networks (e.g., external networks 108 shown in FIG. 1), via intermediate components (e.g., rack switches 106, ADPU 104, and/or the like), facilitating communication with other datacenters, cloud service providers, or wide area networks (WANs). These connections may include pluggable modules (e.g., OSFP modules) or similar high-speed transceivers designed for efficient data transmission as described hereinafter with reference to FIGS. 5-6. The external connections 212 may support various networking protocols, such as Ethernet or InfiniBand® protocols, depending on the requirements for data transfer speed and distance. Each external connection 212 may be linked to the rack connections 206 or insertable switch module 103, allowing for seamless data flow between the server system and external entities. The datacenter rack 101 may also support redundancy in external connections 212 to ensure continuous network availability, even in the event of a failure in one connection.

It should be understood that the datacenter rack 101 described herein is merely one embodiment, and various modifications, substitutions, and alternatives may be made without departing from the scope of the disclosure. The specific components, configurations, and functionalities described are illustrative examples and may vary depending on the specific requirements of the server system or datacenter environment. For example, different types of CPUs, GPUs, memory modules, interconnect switches, and external connections may be used, and the architecture may be adapted to support alternative technologies or configurations. The server datacenter rack 101 may also be implemented in other forms or combined with additional hardware or software components to meet particular performance, scalability, or workload requirements.

### Connections and MBOM/CPO Embodiments

As described above, the embodiments of the present disclosure may leverage various techniques and mechanisms for operably coupling, communicably coupling, etc. the components of the system 100. In high-capacity datacenter networks, such as the network architecture 100 of FIGS. 1-4, the system 100 may leverage optical transceivers that transmit and receive optical signals over optical fibers or other optical communication mediums in order to establish connection between devices in the system 100. As shown in FIG. 5, for example, one or more transceivers 500 alongside corresponding communication mediums may be used to establish communication between datacenter racks (e.g., between insertable switch modules 103), between disaggregated server devices 102, and/or the like.

Accordingly, various different types of optical components and associated assemblies also exist for enabling transmission of signals (optical and/or electrical) between system components and other optoelectronic equipment in a data center. For example, Quad Small Form-factor Pluggable (QSFP) connectors and cables, as well as other forms of connectors such as Small Form Pluggable (SFP) and C-Form-factor Pluggable (CFP) connectors, have long been the industry standard for providing high-speed information operations interface interconnects. More recently, Octal Small Form-factor Pluggable (OSFP) transceivers have come about to provide increased bit rate capabilities. Optical transmitter/receiver systems and optical waveguide structures may be used to interface with components and convert between optical and electrical signals, regardless of the type of optoelectronic connector. The present disclosure contemplates that any type of transceiver may be used to operably couple the components of the present disclosure.

The advent of Mid-Board Optical Modules (MBOM) and Co-Packaged Optics (CPO) also provide an emerging solution for the integration for optics and silicon that address next generation bandwidth and power challenges. With reference to FIG. 6, for example, high-capacity optical switch assemblies may switch multiple channels of data at high data rates, with the number of channels reaching several hundreds and data rates reaching hundreds of Gb/s (Gb/s=109 bits per second). In order to save power, it may be desirable to co-package the switch itself with “optical engines,” which typically are small, high-density optical transceivers located within an application-specific integrated circuit (ASIC) or within an ASIC package together with the switch. The switch assembly may be contained in a rack-mounted case with optical receptacles on its front panel for ease of access. The signals to and from the ASIC may be conveyed to and from the optical receptacles using optical fibers.

Space constraints of the switch and the front panel may limit the number of optical fibers connected to the ASIC and the optical receptacles on the panel. Therefore, the optical signals emitted and received by the switch may be multiplexed using wavelength-division multiplexing, so that each fiber, along with the associated optical receptacle, carries multiple optical signals. For example, each fiber may carry four channels of 100 Gb/s each, at four different, respective wavelengths, to and from the corresponding optical receptacle, for a total data rate of 400 Gb/s (denoted as 4×100 Gb/s).

In many cases, the multiple communication channels carried at different wavelengths on the same fiber are directed to and from different network nodes. For example, each of the 100 Gb/s component signals on a 4×100 Gb/s optical link may be directed to a different server. Therefore, there is a need for an optical cable that is capable of splitting the multiplexed optical signal into multiple component signals at different, respective wavelengths, and is capable of conveying each of these signals to a different network node. For simplicity of installation and use, it is desirable that the optical cable be “active,” meaning that transceivers in the cable convert each of the multiple optical signals to a standard electrical form (and vice versa). As a result, the network nodes need process only electrical signals and will be indifferent to the actual wavelength of the optical channel that is directed to each of them. To further simplify installation and use, it is sometimes desirable that the optical cable be detachable from the transceivers so that a smaller cable may be routed through an installation. Each optical cable may, instead of comprising a transceiver, be designed to mate with a particular transceiver. The transceiver may be connected to a node, such as a server, and be used to connect a connector of each cable to the node as described herein.

Co-packaging may therefore refer to the close integration of different electrical and/or optoelectronic chips in the same package. As shown in FIG. 6, for example, the different chips that constitute the co-packaged system may be assembled on a single substrate in what is typically called the MCM assembly 612. The MCM assembly 612 may include switching circuitry 612 surrounded by peripheral or satellite chips 616. Various example configurations of an MCM assembly 612 are described in further detail herein. In some embodiments, the switching circuitry 612 and surrounding satellite chips 616 are all mounted on a common substrate, although such a configuration is not required. The MCM assembly 612 may be provided in a larger housing of the networking device 606 positioned behind the front panel 608. The switching circuitry 612 may include one or more core digital Application Specific Integrated Circuits (ASICs), CPUs, GPUs, microprocessors, FPGAs, combinations thereof, and the like. The switching circuitry 612 may include a number of input ports and/or output ports 610. The Input/Output (I/O) ports 618 may include electrical ports and/or optical ports. Additionally, the switching circuitry 612 may include a combination of electrical blocks and optical blocks. The electrical blocks of the switching circuitry 612 may include a number of electrical switches that are configured to route signals in an electrical domain. The optical blocks of the switching circuitry 612 may include a number of optical components that are configured to generate, detect, and route signals in an optical domain. The MCM assembly 612, in some embodiments, may concern or include multiple satellite chips 616 that are assembled on the same substrate as the switching circuitry 612. In some embodiments, a configuration of the optical block(s) and a configuration of the electrical block(s) depends (e.g., is based on) on the number of optical ports in the I/O ports 618.

As described above, optical I/Os 610, which may also be referred to as optical connectors, are placed at the front panel 608. As described above, connectivity between the MCM assembly 612 and optical I/Os 610 may be transferred to the front panel 608 through optical fibers. This connection may be made directly with an optical I/O 618 of the switching circuitry or may be made with one or more of the satellite chips 616. The connection is often made with one or more of the satellite chips 616 because the satellite chips 616 may include the electro-optic converters and, possibly, the SERDES to natively support the connection. The satellite chips 616 may include one or more of a DSP processor, driver, trans-impedance amplifier, laser, modulator, photodiode, serializer-deserializer, or the like.

### Example Disaggregated Server Devices

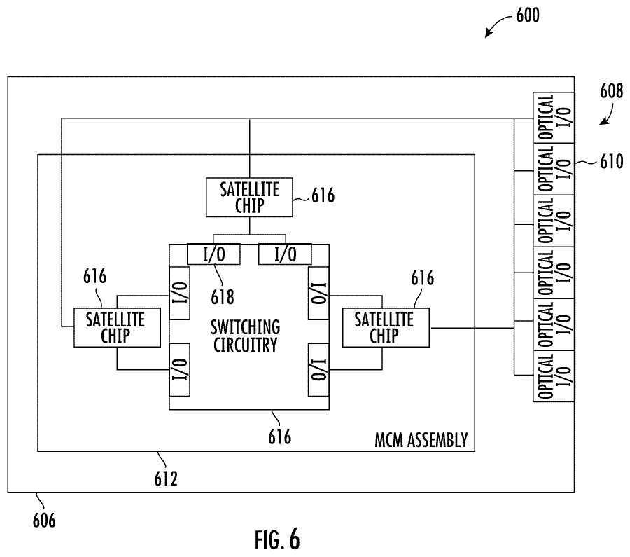

With reference to FIGS. 7-9B, various datacenter racks 101 formed of networking chassis (e.g., first networking chassis 105, second networking chassis 107, etc.) are illustrated. An example first networking chassis 105, as shown, may include at least a first disaggregated server device 102 and an insertable switch module 103 as described above. The networking chassis 105, 107 of the present disclosure may refer to the structure configured to support, or otherwise house the disaggregated server device(s) 102 and insertable switch module(s) 103. As such, the networking chassis may be configured and dimensioned (e.g., sized and shaped) to support one or more disaggregated server devices 102 and one or more insertable switch modules 103 at least partially therein. As illustrated in FIG. 7-9B, the datacenter rack 101 and the networking chassis 105, 107 therein may include a plurality of disaggregated server devices 102 and insertable switch modules 103.

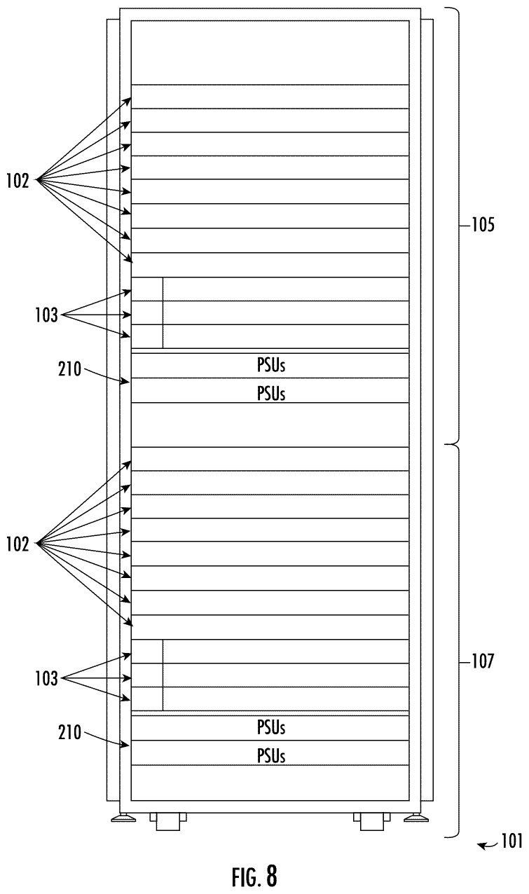

By way of a nonlimiting example, as shown in FIGS. 8 and 9A, an example first networking chassis 105 may include eight (8) disaggregated server devices 102 and three (3) insertable switch modules 103. The present disclosure, however, contemplates that the networking chassis 105, 107 may include any number of disaggregated server devices 102 and insertable switch modules 103 based on the intended application of the networking chassis 105, 107. Furthermore, the present disclosure contemplates that the ordering, relative positioning, etc. of the disaggregated server devices 102 and insertable switch modules 103 may vary based on the intended application of the networking chassis 105, 107. Still further, although illustrated with a first and a second networking chassis 105, 107 in FIG. 8, the present disclosure contemplates that an example datacenter rack 101 may include any number of networking chassis based on the intended application of the datacenter rack.

Each of the disaggregated server devices 102 and insertable switch modules 103 may further be removably attached with the networking chassis 105, 107. As described herein, the embodiments of the present disclosure provide a modular, scalable building block for large AI applications that eliminate or otherwise minimize the density concerns of conventional solutions. As such, the disaggregated server devices 102 and insertable switch modules 103 may each be removed without impacting the operations of other disaggregated server devices 102 and insertable switch modules 103 within the networking chassis. By way of a nonlimiting example, in an instance in which a first disaggregated server device 102 (e.g., any disaggregated server device 102) of the first networking chassis 105 requires replacement (e.g., scheduled maintenance, component failure, etc.), the first disaggregated server device 102 may be removed from the first networking chassis 105 without the removal of other disaggregated server devices 102 and/or insertable switch modules 103. In conventional solutions with multiple GPUs per server device, however, the replacement of an example faulty GPU results in the removal of additional GPUs on the same server device that do not require replacement.

In some embodiments, the datacenter rack 101 and/or the networking chassis 105, 107 may include one or more power supply units (PSUs) 210 or power delivery units (PDUs) 210. By way of example, in some embodiments, an example power supply unit (PSU) 210 may be configured to provide a direct current (DC) power input to the disaggregated server devices 102 and/or the insertable switch modules 103. Additionally or alternatively, in some embodiments, the power delivery units (PDUs) 210 may be configured to distribute power received by the networking chassis 105, 107 and/or the datacenter rack 101 to the disaggregated server devices 102 and/or the insertable switch modules 103. The present disclosure contemplates that the networking chassis 105, 107 and the datacenter rack 101 may employ any power source or technique for supplying power to the components described herein.

With reference to FIGS. 10A-10B, an example disaggregated server device 102 (e.g., an example first distributed server device 102) is illustrated. As shown, the disaggregated server device 102 may include a module 300 that includes the CPU 202 (e.g., an example first CPU 202) and the GPU 208 (e.g., an example first GPU 208), one or more first thermal management components 400, and a connector 109. The GPU 208 and/or the CPU 202 may be isolated on the first disaggregated server device 102, and the GPU 208 and/or the CPU 202 may be the only GPU 208 and/or CPU 202 on the first disaggregated server device 101. Said differently, the first GPU 208 and/or the first CPU 202 may be supported on the first disaggregated server device 102 in the absence of other GPUs 208 or other CPUs 202 on the first disaggregated server device 102. As described above, by limiting the number of GPUs 208 and/or CPUs 202 on each disaggregated serve device 102, the embodiments of the present disclosure may address the density concerns of conventional solutions. The first CPU 202 and the first GPU 208 may be configured to perform one or more computing operations associated with the networking chassis 105 as described hereafter, the example disaggregated server device 102 may further include a connector 109 that may, in operation, communicably and operably coupled the module 300 of the disaggregated server device 102 with an example cable cartridge.

The one or more thermal management components 400 of the disaggregated server device 102 may be configured to independently dissipate heat generated by the first CPU 202 and/or the first GPU 208. Unlike conventional solutions that increase the number of computing devices per server or node thereby limiting the availability of thermal solutions, by including only a single CPU 202 and single GPU 208 on the disaggregated server device 102, the embodiments of the present disclosure may increase the amount of heat that may be dissipated from the disaggregated server device 102. Said differently, the removal of additional computing components from the node provides additional space to include more thermal management devices 400. In some embodiments, the one or more thermal management components may be fans that are configured to dissipate heat generated by the first CPU 202 and/or the first GPU 208 (e.g., via convective cooling). Although described herein with reference to example air cooling based techniques, the present disclosure contemplates that the one or more thermal management components may include any mechanism, structure, device, etc. for dissipating heat (e.g., air-based, fluid-based, etc.).

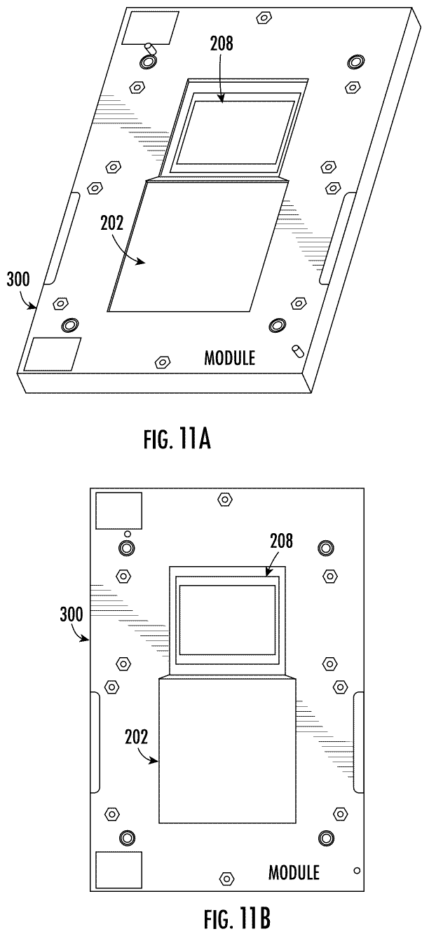

With reference to FIGS. 11A-11B, an example module 300 for supporting the CPU 202 (e.g., the example first CPU 202) and the GPU 208 (e.g., the example first GPU 208) is illustrated. As described above, the CPU 202 may be configured to manage overall operations within a datacenter rack 101 (e.g., associated with a particular disaggregated server devices 102). The CPU 202 may execute instructions, process data, and control communication between the other components, and the CPU 202 may communicate with the GPUs 208, enabling the CPU 202 to offload specialized computing tasks such as graphics rendering, AI, and ML workloads, and/or the like. As illustrated in FIGS. 11A-11B and described herein, the module 300 for each disaggregated server device 102 may include only a single GPU 208 and/or a single CPU 202 so as to enable the modularity of the present disclosure without impacting the operational capabilities of the networking chassis and datacenter rack 101. Although described herein with reference to a first disaggregated server device 102 of the first networking chassis 105, the present disclosure contemplates that any disaggregated server device 102 in any networking chassis 105, 107 may include the configuration of the first disaggregated server device 102.

The GPUs 208 may provide specialized processing capabilities for parallel computation tasks, such as those involved in AI, ML, and data-intensive computing workloads. Each GPU 208 may be connected to a respective CPU 202 allowing the CPU 202 to offload certain tasks to the GPUs 208 for faster processing. The single GPUs 208 per disaggregated server device of the networking chassis may be configured to communicate with one another, either directly or through insertable switch module 103, to enable coordinated parallel processing and data sharing. The GPUs 208 may include HBM for faster access to data during computation. The number and type of GPUs 208 in the system may be scalable, allowing the architecture to accommodate varying performance needs depending on the specific workload. For example, the GPUs 208 may include NVIDIA® H100 Tensor Core GPUs, NVIDIA® Hopper™ GPUs, or the like optimized for deep learning and AI inference, or NVIDIA® A100 GPUs designed for high-performance computing and data analytics.

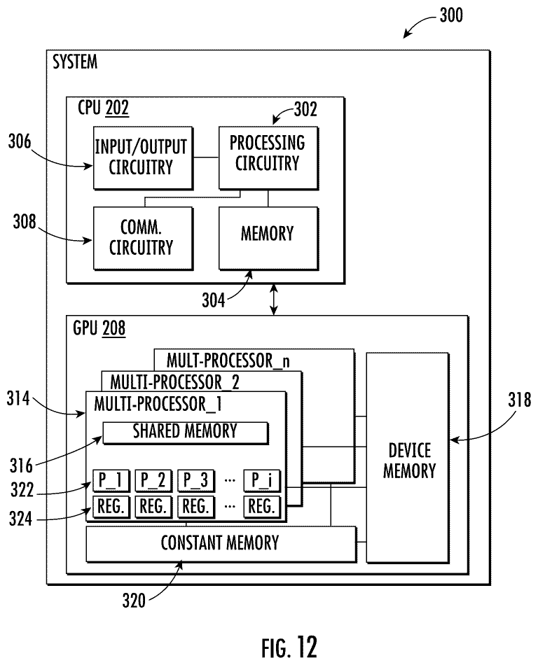

The CPU 202 and the GPUs 208 may collectively serve as the system (described in further detail in FIG. 12) responsible for performing various functionalities described in the disclosure. In such a configuration, the CPU 202 may handle general-purpose processing and control operations, while the GPUs 208 may focus on parallel processing tasks, particularly those involving data-intensive computations. In specific embodiments, the system, or portions or components thereof, may be embodied as or include a chip or chipset. In other words, the system may include physical packages (e.g., chips) including materials, components, and/or wires on a structural assembly (e.g., a baseboard). The structural assembly may provide physical strength, conservation of size, and/or limitation of electrical interaction for component circuitry included thereon. The system, may therefore, in some cases, be configured to implement an embodiment of the disclosure on a single chip or as a single “system on a chip (SoC).” As such, in some cases, a chip or chipset may constitute means for performing one or more operations for providing the functionalities described herein. In this configuration, the CPU 202 may be coupled to a GPU 208 via die-to-die (D2D) interconnects, chip-to-chip (C2C) interconnects, such as a Ground-Referenced Signaling (GRS) interconnect, and/or the like, allowing for low-latency communication and high bandwidth between the CPU 202 and GPU 208. Additionally, the CPU 202 may connect to multiple GPUs 208 (e.g., GPUs of other disaggregated server devices 102) using both D2D/C2C interconnects and high-speed interconnects, such as PCIe interconnects.

### Example Computing Module

With reference to FIG. 12, a schematic diagram of example circuitry, some or all of which may be included in a module 300 is illustrated. The module 300 may include a CPU 202 (e.g., the example first CPU 202) and a GPU 208 (e.g., the example first GPU 208). The CPU 202 may include components such as a processing circuitry 302, memory 304, input/output circuitry 306, and communications circuitry 308. The GPU 208 may include a plurality of multi-processors 314, a shared memory 316, a device memory 318, a plurality of processors P_1, P_2, . . . , P_i 322 for each multi-processor 314, a plurality of registers 324 for each multi-processor 324, and a constant memory 320. It should be understood that FIG. 12 is merely an illustrative embodiment and the module 300 may include more components, fewer components, or different components than those depicted. The arrangement of the components may also vary. Depending on specific implementation requirements, the module 300 may incorporate additional components or omit certain components. For instance, the system may include a CPU 202 that is operatively coupled to multiple GPUs of other disaggregated server device 102, where the GPUs 208 are operatively interconnected using high-speed interconnects such as NVLink (e.g., of the insertable switch device 103), enabling efficient data sharing and parallel processing. Additionally or alternatively, the system may include multiple CPUs 202, such as of other disaggregated server devices 102, that may be operatively interconnected via PCIe links, allowing for coordinated processing and workload distribution across the CPUs 202. In some configurations, both CPUs 202 and GPUs 208 (e.g., the single CPU 202 and single GPU 208 of the same disaggregated server device 102) may be interconnected using a combination of PCIe, NVLink, or other high-speed interconnect technologies.

In the module 300, the CPU 202 may serve as the primary processing unit responsible for general-purpose computation and control operations associated with one or more functions described herein. For instance, the CPU 202 may execute instructions, manage data flow, and coordinate the activities of other components associated with the networking chassis 105, 107. The CPU 202 may include various circuitries, such as processing circuitry 302 for performing arithmetic and logical operations, memory 304 for storing data and instructions, input/output circuitry 306 for interfacing with external devices, communications circuitry 308 for handling data exchange with other systems or networks. As such, the CPU 202 may be configured to handle a wide range of workloads, including data processing, task scheduling, and control functions, enabling it to support various applications depending on the specific requirements of the module 300.

Although the term “circuitry” as used herein is described in some cases using functional language, it should be understood that the particular implementations necessarily include the use of particular hardware configured to perform the functions associated with the respective circuitry as described herein. It should also be understood that certain components may include similar or common hardware. For example, two sets of circuitries may both leverage use of the same processing circuitry, communication circuitry, memory, or the like to perform their associated functions, such that duplicate hardware is not required for each set of circuitries. It will be understood in this regard that some of the components described in connection with the module 300 may be housed together, while other components are housed separately. While the term “circuitry” should be understood broadly to include hardware, in some embodiments, the term “circuitry” may also include software for configuring the hardware. In some embodiments, other elements of the module 300 may provide or supplement the functionality of particular circuitry. For example, the processing circuitry 302 may provide processing functionality, the memory 304 may provide storage functionality, the communications circuitry 308 may provide network interface functionality, and the like.

The processing circuitry 302 may be embodied in a number of different ways and may, for example, include one or more processing circuitries configured to perform independently. Additionally, or alternatively, the processing circuitry 302 may include one or more processors configured in tandem via a bus to enable independent execution of instructions, pipelining, and/or multithreading. The processing circuitry 302 may, for example, be embodied as various means including one or more microprocessors with accompanying digital signal processor(s), one or more processor(s) without an accompanying digital signal processor, one or more coprocessors, one or more multi-core processors, one or more controllers, processing circuitry, one or more computers, various other processing elements including integrated circuits such as, for example, an ASIC (application specific integrated circuit) or FPGA (field programmable gate array), or some combination thereof. The use of the term “processing circuitry” may be understood to include a single core processor, a multi-core processor, multiple processors internal to the apparatus, and/or remote or “cloud” processors. Accordingly, although illustrated in FIG. 12 as a single processor, in some embodiments, the processing circuitry 302 may include a plurality of processors. The plurality of processors may be embodied on a single computing device or may be distributed across a plurality of computing devices configured to function collectively. The plurality of processors may be in operative communication with each other and may be collectively configured to perform one or more functionalities of the module 300 as described herein.

In an example embodiment, the processing circuitry 302 may be configured to execute instructions stored in the memory 304 or otherwise accessible to the processing circuitry 302. Alternatively, or additionally, the processing circuitry 302 may be configured to execute hard-coded functionality. As such, whether configured by hardware or software methods, or by a combination thereof, the processing circuitry 302 may represent an entity (e.g., physically embodied in circuitry) capable of performing operations according to an embodiment of the present disclosure while configured accordingly. Alternatively, as another example, when the processing circuitry 302 is embodied as an executor of software instructions, the instructions may specifically configure the processing circuitry 302 to perform one or more algorithms and/or operations described herein when the instructions are executed. For example, these instructions, when executed by the processing circuitry 302, may cause the module 300 to perform one or more of the functionalities thereof as described herein.

The memory 304 may be non-transitory and may include, for example, one or more volatile and/or non-volatile memories, or some combination thereof. In other words, for example, the memory 304 may be an electronic storage device (e.g., a non-transitory computer readable storage medium). The memory 304 may be configured to store information, data, content, applications, instructions, or the like, for enabling an apparatus (e.g., the module 300) to carry out various functions in accordance with example embodiments of the present disclosure. Although illustrated in FIG. 12 as a single memory, the memory 304 may comprise a plurality of memory components. The plurality of memory components may be embodied on a single computing device or distributed across a plurality of computing devices. In various embodiments, the memory 304 may comprise, for example, a hard disk, random access memory (RAM), virtual memory, non-volatile memory (NVRAM), cache memory, flash memory, a compact disc read only memory (CD-ROM), digital versatile disc read only memory (DVD-ROM), an optical disc, circuitry configured to store information, or some combination thereof. The memory 304 may be configured to store information, data, applications, instructions, or the like for enabling the module 300 to carry out various functions in accordance with example embodiments discussed herein. For example, in at least some embodiments, the memory 304 may be configured to buffer data for processing by the processing circuitry 302. Additionally, or alternatively, in at least some embodiments, the memory 304 may be configured to store program instructions for execution by the processing circuitry 302. The memory 304 may store information in the form of static and/or dynamic information. This stored information may be stored and/or used by the module 300 during the course of performing its functionalities.

In some embodiments, the processing device 302 further includes input/output circuitry 306 that may, in turn, be in communication with the processing circuitry 302 to provide an audible, visual, mechanical, or other output and/or, in some embodiments, to receive an indication of an input from a user or another source. In that sense, the input/output circuitry 306 may include means for performing analog-to-digital and/or digital-to-analog data conversions. The input/output circuitry 306 may interface with one or more units, devices, sensors, actuators, communication modules, storage devices, external processing units, peripheral devices, and/or the like. These outputs may then be transmitted to one or more destinations, such as display units, storage systems, control systems, processors (e.g., processing circuitry 302), network interfaces, peripheral devices, external systems, and/or the like, for further action.

In some embodiments, the input/output circuitry 306, in combination with one or more components described herein (e.g., processing circuitry 302) may be configured to control one or more functions of a display or one or more user interface elements through computer-program instructions (e.g., software and/or firmware) stored on a memory accessible to the processing circuitry 302 (e.g., the memory 304, and/or the like). In some embodiments, aspects of input/output circuitry 306 may be reduced as compared to embodiments where the module 300 may be implemented as an end-user machine or other type of device designed for complex user interactions. In some embodiments (like other components discussed herein), the input/output circuitry 306 may be eliminated from the module 300. Although more than one input/output circuitry can be included in the module 300, only one is shown in FIG. 12 to avoid overcomplicating the disclosure (e.g., as with the other components discussed herein).

The communications circuitry 308, in some embodiments, includes any means, such as a device or circuitry embodied in either hardware, software, firmware or a combination of hardware, software, and/or firmware, that is configured to receive and/or transmit data from/to a network and/or any other device, or circuitry associated therewith. In this regard, the communications circuitry 308 may include, for example, a network interface for enabling communications with a wired or wireless communication network. For example, in some embodiments, communications circuitry 308 may be configured to receive and/or transmit any data that may be stored by the memory 304 using any protocol that may be used for communications between computing devices. For example, the communications circuitry 308 may include one or more network interface cards, antennae, transmitters, receivers, buses, switches, routers, modems, and supporting hardware and/or software, and/or firmware/software, or any other device suitable for enabling communications via a network. Additionally, or alternatively, in some embodiments, the communications circuitry 308 may include circuitry for interacting with the antenna(s) to cause transmission of signals via the antenna(e) or to handle receipt of signals received via the antenna(e). These signals may be transmitted by the module 300 using any of a number of wireless personal area network (PAN) technologies, such as Bluetooth® v1.0 through v5.0, Bluetooth Low Energy (BLE), infrared wireless (e.g., IrDA), ultra-wideband (UWB), induction wireless transmission, or the like. In addition, it should be understood that these signals may be transmitted using Wi-Fi, Near Field Communications (NFC), Worldwide Interoperability for Microwave Access (WiMAX) or other proximity-based communications protocols.

The circuitries of the CPU may be connected through various interconnect architectures, depending on their physical arrangement and implementation within the module 300. Within the CPU 202, different circuitries such as the processing circuitry 302, memory 304, input/output circuitry 306, and/or communications circuitry 308, may be linked through internal buses or interconnect fabrics that facilitate data transfer between these components. For example, the CPU 202 may use an internal crossbar switch or ring bus architecture to interconnect these circuitries, providing a pathway for data to move efficiently between the processing cores, cache memory, and other functional units. In some configurations, the CPU 202 may employ a hierarchical bus structure, where a front-side bus (FSB) connects the processing circuitry 302 to the memory 304, while a separate bus (e.g., a peripheral bus) connects the input/output circuitry 306 and/or communications circuitry 308. The internal interconnects may also be configured to support coherent memory access, ensuring that changes to data in one part of the CPU are reflected across other connected components.

Accordingly, non-transitory computer readable storage media, which may, for example, be the memory 304, can be configured to store firmware, one or more application programs, and/or other software, which include instructions and/or other computer-readable program code portions that can be executed to direct operation of the module 300 to implement various operations, including the examples described herein. As such, a series of computer-readable program code portions may be embodied in one or more computer-program products and can be used, with a device, module 300, database, and/or other programmable apparatus, to produce the machine-implemented processes discussed herein. It is also noted that all or some of the information discussed herein can be based on data that is received, generated and/or maintained by one or more components of the module 300. In some embodiments, one or more external systems (such as a remote cloud computing and/or data storage system) may also be leveraged to provide at least some of the functionality discussed herein.

### Example GPU

The GPU 208 in the module 300 may serve as a specialized processing unit designed to handle parallel computational tasks, such as those involved in graphics rendering, AI, ML, and other data-intensive workloads. The GPU 208 may include various components to support its high-performance capabilities, such as a plurality of multi-processors 314, which may each comprise a set of individual processing units (P_1, P_2, . . . , P_i) 322. Each multi-processor 314 may also include its own shared memory 316 to facilitate efficient data access and communication between the processors within the multi-processor. Additionally, the GPU 208 may include device memory 318, which serves as the primary storage for data processed by the GPU, and constant memory 320, which may be used to store read-only data that remains constant throughout the execution of specific tasks.

The multi-processors 314 may be configured to operate in parallel, allowing the GPU 208 to execute multiple threads simultaneously, thereby accelerating tasks that can be divided into smaller, concurrent operations. Each multi-processor 314 may include a set of registers 324 associated with its processors, which provide fast access to frequently used data during computation. The use of shared memory 316 within each multi-processor 314 may help reduce latency and improve throughput by allowing data to be quickly shared between threads without needing to access device memory 318.

The device memory 318 may serve as the main memory resource for the GPU 208 and may include various types of memory, such as GDDR (Graphics Double Data Rate) memory or high-bandwidth memory (HBM), depending on the performance requirements of the system. The device memory 318 may be used to store large datasets, textures, or other information needed for processing tasks, and may be accessible by both the GPU 208 and, in some configurations, the CPU 202. The constant memory 320 may be used for data that does not change during processing, such as configuration parameters or lookup tables, which can be accessed quickly by the processors 322 without incurring additional latency.

The GPU 208 may support various interconnect architectures for communication between the multi-processors 314, shared memory 316, and other components within the module 300. For instance, the GPU 208 may include an internal crossbar switch or ring interconnect that enables data flow between the multi-processors 314, shared memory 316, and device memory 318. In configurations where the GPU 208 is operatively coupled to one or more additional GPUs of other disaggregated server devices 102, high-speed interconnects such as NVLink (e.g., via the insertable switch module 103) may be used to facilitate data transfer and sharing of memory resources across multiple GPUs, thus enhancing parallel processing capabilities for large-scale computations.

In some embodiments, the CPU 202 and the GPU 208 may be operatively coupled through various interconnect architectures, depending on their physical arrangement and implementation within the module 300. In embodiments where both the CPU 202 and GPU 208 are integrated onto the same SoC, their circuitries may communicate through high-speed interconnects designed for low latency and high bandwidth. In this configuration, the CPU 202 and GPU 208 can share a unified memory space, allowing them to access common data efficiently without the overhead associated with data transfer between separate components. In embodiments where the CPU 202 and GPU 208 are on different SoCs, their circuitries may connect via PCIe buses or similar high-speed interfaces, allowing for data exchange. In example embodiments of such a scenario, each SoC may have its own dedicated memory, and data may need to be transferred explicitly between the CPU's memory (e.g., memory 304) and the GPU's memory (e.g., device memory 318). Additionally, when CPU 202 and GPU 208 are housed within the same server but on separate motherboards, they may be connected through interconnects such as NVLink® interconnects, which is designed for high-speed communication between CPU(s) 202 and GPU(s) 208, as described above. Such an approach may allow for greater bandwidth compared to traditional PCIe connections and enables faster data sharing, which is beneficial for applications that demand rapid access to large datasets. Overall, the connectivity of the various circuitries within the module 300 can take multiple forms depending on the design choices made during implementation. Each configuration offers different trade-offs in terms of performance, scalability, and complexity, and the chosen architecture may be optimized based on the specific workload requirements and performance goals of the system.

The module 300 may be configured to support a wide range of operations across different domains, depending on the specific implementation requirements and the configuration of its components. For example, the module 300 may be used to perform simulation operations, including but not limited to simulating physical processes, validating software for autonomous machines, or conducting hardware testing in a virtual environment. The module 300's capability to handle parallel processing tasks through the GPU 208 and general-purpose processing through the CPU 202 enables the module 300 to efficiently execute simulations with high computational demands. Additionally, the module 300 may facilitate digital twin operations, where real-world processes are mirrored digitally to monitor, optimize, or predict system behavior.

In embodiments where graphics rendering or light transport simulation is required, such as in virtual reality (VR), augmented reality (AR), or mixed reality (MR) applications, the module 300 may utilize the GPU 208's multi-processors 314 and high-bandwidth memory 318 to render complex visual effects and simulations in real time. The module 300's input/output circuitry 306 may interface with VR/AR/MR display devices to present immersive content to users, while the communications circuitry 308 may support data exchange between the module 300 and external devices or cloud-based services. The parallel computing capabilities of the module 300 may also be employed to accelerate deep learning tasks, such as training or inferencing with neural networks for tasks like object detection, natural language processing, or image recognition.

The module 300 may further support generative AI operations, including the use of large language models (LLMs) for text generation, content creation, and natural language understanding. The processing circuitry 302 may execute algorithms and models designed for generative AI applications, while the GPU 208 may accelerate the computations required for training large-scale models or performing high-dimensional data analysis. The module 300 may also serve as a platform for synthetic data generation, which may be used for model training or testing in environments where real data is limited or unavailable.

In some configurations, the module 300 may be implemented at an edge device, such as a sensor-equipped device in a remote or resource-constrained environment. Alternatively, the module 300 may be deployed in a cloud computing environment, where multiple instances of the system may be interconnected to create a highly scalable and distributed architecture. The module 300 may also support the deployment of Virtual Machines (VMs) to provide isolated environments for running diverse workloads. Furthermore, the collaborative use of the system for 3D content creation platforms may enable multiple users to work on 3D asset development in real time, leveraging the system's high-performance capabilities for rendering and data processing.

Accordingly, the module 300's modular and flexible architecture allows it to support a variety of applications, from traditional computing and data processing to cutting-edge technologies like generative AI, VR/AR, and digital twins. The capabilities of the system may be tailored to specific use cases by selecting appropriate hardware configurations, interconnect architectures, and software frameworks.

### Example Insertable Switch Module

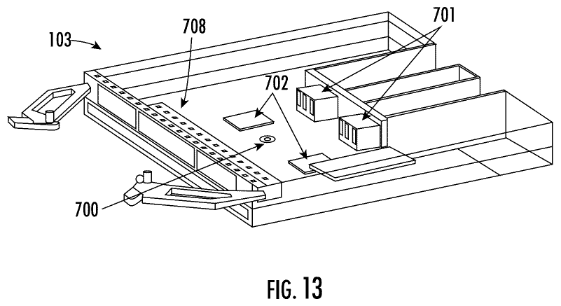

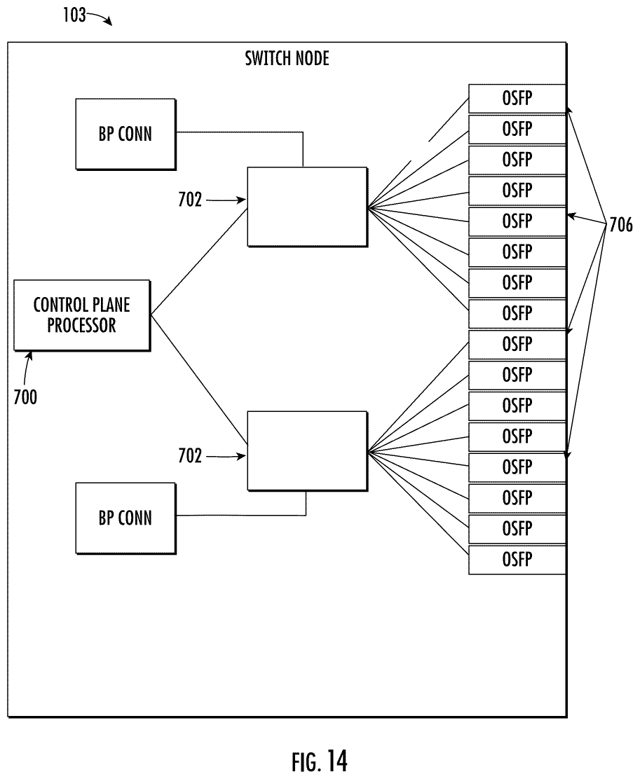

With reference to FIGS. 13-14, an example insertable switch module 103 is illustrated. As described above, the insertable switch module 103 may facilitate or partially control communication between the components (e.g., a single CPU 202 and a single GPU 208) of the disaggregated server devices 102. For example, the insertable switch module 103 may be configured to enable high-speed data transfer and coordination for parallel processing tasks. The insertable switch module 103 may include switching chipsets, fabric management controllers, and/or other communication hardware that may be traditionally supported by the server device (e.g., as part of the CPU and GPU configuration). The components of the insertable switch module 103 may include various types of interconnect technologies, such as NVIDIA® NVSwitches (e.g., NVLink® switches) or other high-performance fabric switches, depending on the system configuration. The high-speed insertable switch module 103 may allow multiple GPUs 208 to be interconnected in a fully integrated fabric, providing low-latency, high-bandwidth communication between the GPUs for efficient execution of AI, ML, and high-performance computing tasks. The insertable switch module 103 may support scalability, allowing additional GPUs 208 to be added to the system as needed. These insertable switch module 103 may also manage data flow between GPUs 208 and the CPU 202 via the rack connections 206, optimizing data throughput for complex computational workloads. In some configurations, the insertable switch module 103 may support hybrid or optical interconnect technologies to enhance performance based on system requirements.

The insertable switch module 103 may include one or more first switching chipsets 702 and a first fabric management controller 700 operably coupled with the one or more first switching chipsets 702. The first insertable switch module 103 may be configured to at least partially control data transmission associated with the first disaggregated server device 102. The insertable switch modules 103 may further include various ports 706, such as for operably coupling the insertable switch modules with the disaggregated server devices 102, rack switches 106, or any other device of the system 100. The fabric management controller 700 may operate to configure the NVSwitch memory fabrics to form one memory fabric among all participating GPUs 208 and monitor the NVLinks® that support the fabric. The fabric management controller 700 may include any circuitry components, such as those described with reference to the CPU 202 and/or GPU 208 of the module 300 above, configured to route data among NVSwitch ports, coordinates with the GPU 208 drivers to initialize GPUs 208, and/or monitor the fabric for NVLink® and NVSwitch errors. The one or more first switching chipsets 702 may include any circuitry components, such as those described with reference to the CPU 202 and/or GPU 208 of the module 300 above, for effectuating the instructions of the fabric management controller 700.

The insertable switch module 103 may, similar to the disaggregated server device 102, include one or more first switch thermal management components 708 are configured to independently dissipate heat generated by the one or more first switching chipsets 702 and/or the first fabric management controller 700. Unlike conventional solutions that increase the number of computing devices per server or node thereby limiting the availability of thermal solutions, including only the communication hardware 700, 702 on a single node, the embodiments of the present disclosure may increase the amount of heat that may be dissipated from the insertable switch device 103. Said differently, the removal of additional computing components from the node provides additional space to include more thermal management devices 708. In some embodiments, the one or more thermal management components may be fans that are configured to dissipate heat generated by the first switching chipsets 702 and/or the first fabric management controller 700 (e.g., via convective cooling). Although described herein with reference to example air cooling based techniques, the present disclosure contemplates that the one or more switch thermal management components may include any mechanism, structure, device, etc. for dissipating heat (e.g., air-based, fluid-based, etc.). The insertable switch module 103 may further include connectors 701 that may, in operation, communicably and operably couple the insertable switch module 103 with an example cable cartridge.

### Example Cable Cartridges

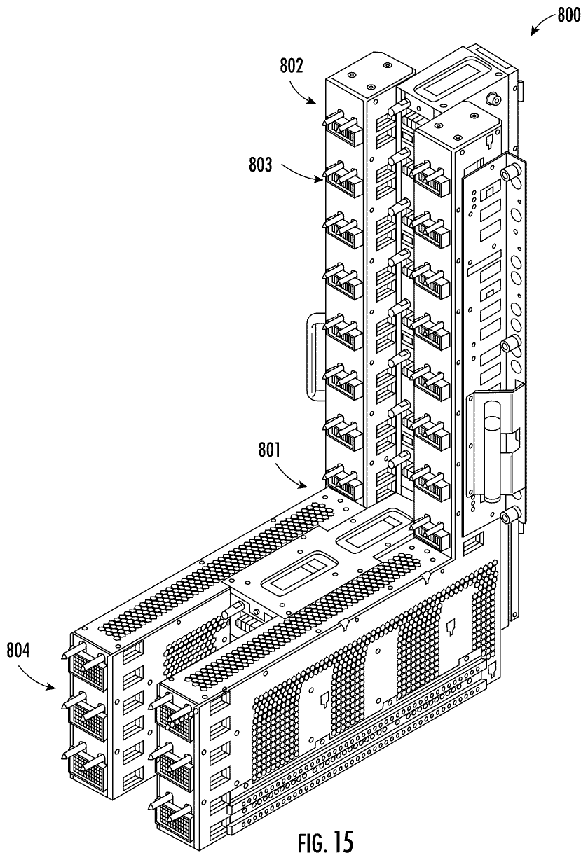

With reference to FIGS. 15-17, an example cable cartridge 800 of the present disclosure is illustrated. As shown, the cable cartridge 800 may include a housing 801 defining a first portion 802 and a second portions 804. The first portion 802 may be configured to be coupled with at least a first disaggregated server device 102 supported by a networking chassis 105, 107. By way of continued example, the first portion 802 of the cable cartridge 800 may be configured to physically interface with the connector 109 of the example disaggregated server devices 102 described herein. The second portion 804 may be configured to be coupled with at least a first insertable switch module 103 supported by the networking chassis 105, 107. By way of continued example, the second portion 804 of the cable cartridge 800 may be configured to physically interface with the connector 701 of the example insertable switch modules 103 described herein. In doing so, the cable cartridge may operate to operably couple an example first disaggregated server device 102 and an example first insertable switch module 103. The present disclosure contemplates that the configuration and dimensions (e.g., size and shape) of the housing 801 may vary based on the configuration of the networking chassis 105, 107, the disaggregated server devices 102, and/or the insertable switch module 103. In some embodiments, the cable cartridge 800 may be configured to operably couple each of the disaggregated server devices 102 and the insertable switch modules 103 of the example networking chassis 105, 107.

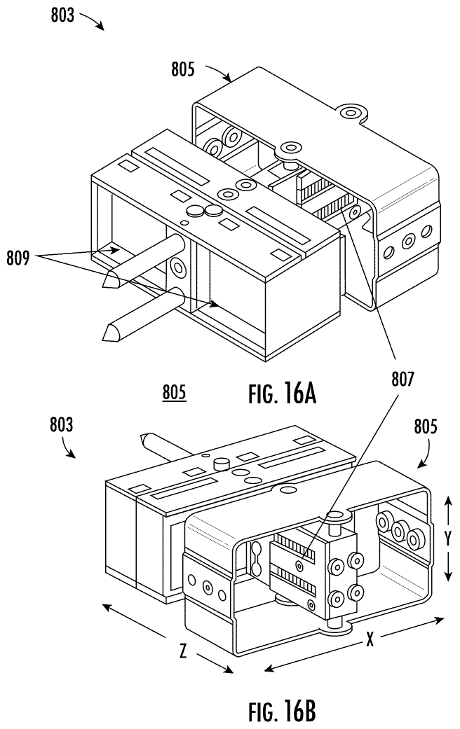

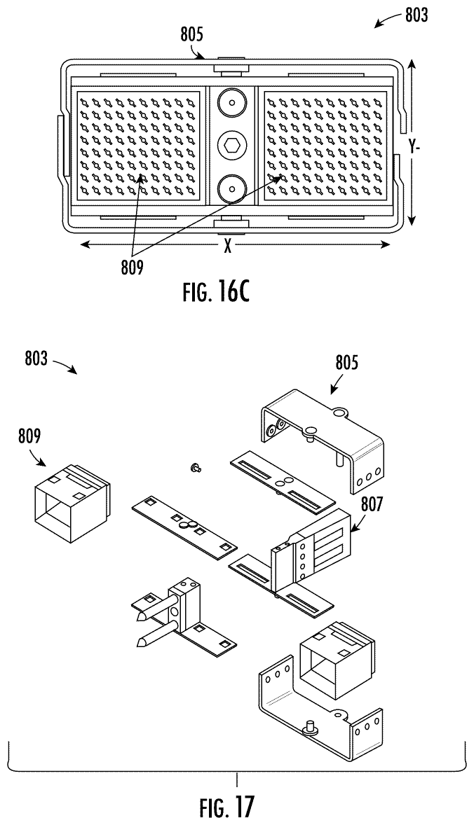

With reference to FIGS. 16A-17, the cable cartridge 800 may include an attachment mechanism 803 that may be configured to removable attach at least the first portion 802 of the housing 801 with the first disaggregated server device 102. By way of example, the attachment mechanism 803 may include a float frame 805 configured to receive a connector 109 of the first disaggregated server device 102 therein. The float frame may be configured to enable movement of the connector 109 that interfaces with corresponding connector 809 within the attachment mechanism 803 in at least a first direction (X) relative to the float frame 805 and/or in a second direction (Y) substantially perpendicular to the first direction (X). In some embodiments, the float frame 803 may include a load control device 807 configured to maintain connection between the first disaggregated server device 102 and the cable cartridge 800. By way of example, the load control device 807 may include at least a first spring configured to urge the attachment mechanism 803 in a third direction (Z) that is substantially perpendicular to the first direction (X) and the second direction (Y). In doing so, the attachment mechanism of the cable cartridge 800 may enable the cable cartridge 800 to interface with disaggregated server device 102 and/or insertable switch modules 103 of varying dimensions.

### Example Logical Network

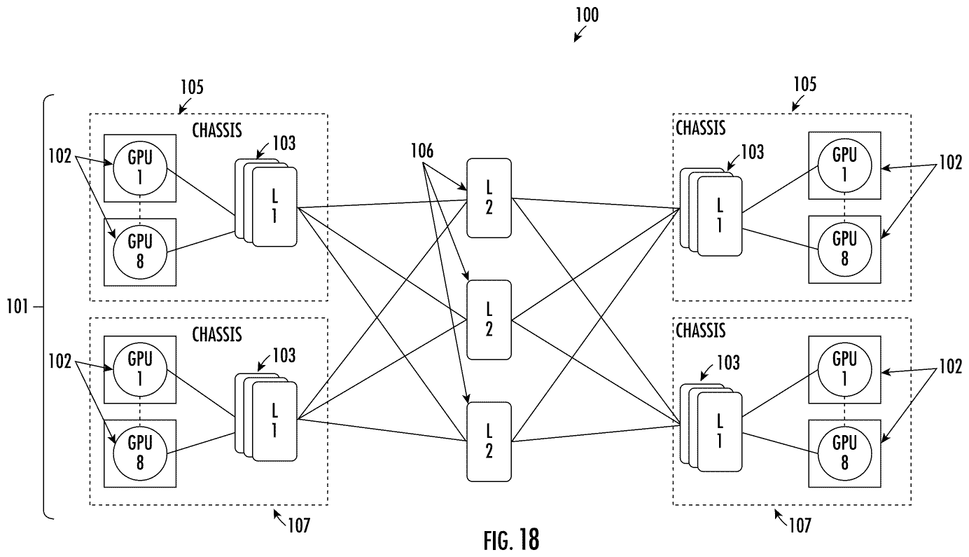

With reference to FIG. 18, a logical representation of a networking configuration 100 is illustrated. The networking configuration 100 may operate as an example implementation of the networking chassis 105, 107, disaggregated server devices 102, and/or insertable switching modules 103 of the present disclosure. As shown, the first network domain may refer to the datacenter rack 101 that includes a first networking chassis 105 and a second networking chassis 107. Each of the first networking chassis 105 and the second networking chassis 107 may include a plurality of disaggregated server devices 102 that operate as GPU nodes in the network 100. Each of the first networking chassis 105 and the second networking chassis 107 may further include a plurality of insertable switch modules 103 as described herein. The insertable switch modules 103 may operably couple the datacenter rack 101 with a second network domain include a plurality of rack switches 106 such as those described above with reference to FIG. 1.

### Example Methods

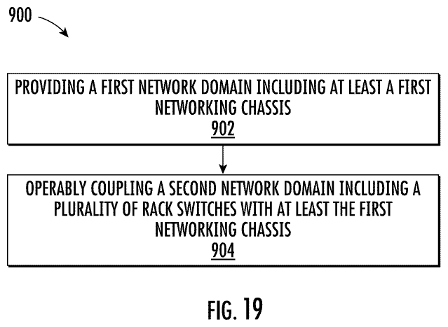

With reference to FIG. 19, an example method for connecting an example networking configuration 900 is illustrated. As shown in operation 902, the method 900 may include providing a first network domain including at least a first networking chassis 105. The first networking chassis 105 may be of a first datacenter rack 101 and may include a first disaggregated server device 102 supported by the first networking chassis 105 that includes a first CPU 202 and a first GPU 208 coupled with the first CPU 202 as described above. As described herein, the first GPU 208 may be the only GPU 208 of the first disaggregated server device 108 so as to enable to modularity benefits described herein. The first networking chassis may further include a first insertable switch module 103 communicably coupled with the first disaggregated server device 102. The first insertable switch device 103 may include one or more first switching chipsets 702 and a first fabric management controller 700 operably coupled with the one or more first switching chipsets 702 as described above. As illustrated and described herein, the first networking chassis may include a plurality of insertable switch modules 103 and/or a plurality of disaggregated server devices 102, such that operation 902 includes the connection of each of these components within the first networking chassis 105.

For example, operation 902 may include the physical attachment of each of the insertable switch modules 103 withing the first networking chassis 105. Similarly, operation 902 may include the physical attachment of each of the disaggregated server devices 102 withing the first networking chassis 105. Furthermore, operation 902 may include the operable coupling of these components, such as via the cable cartridge 800 described above. Given the modularity provided by the single GPU 208 disaggregated server devices 102, and the placement of communication hardware on a dedicated insertable switch module, the attachment and/or replacement of these components within the first networking chassis 105 is improved relative to conventional solutions.

Thereafter, as shown in operation 904, the method may include operably coupling a second network domain with the first networking chassis 105. As described above, the second domain may include a plurality of rack switches 106. The rack switches 106 that may operably couple the datacenter racks 101 to external networks 108 and or any other networking component. By ways of example, the rack switches 106 may be communicably coupled with the insertable switch modules 103 of the datacenter rack 101. The rack switches 106 may manage and route data between the datacenter racks 101, via the insertable switch modules 103. Although described with reference to a first and second domain, the present disclosure contemplates that operation 904 may further include the operable coupling of additional network layers, domains, etc. based on the intended application for the components described herein.

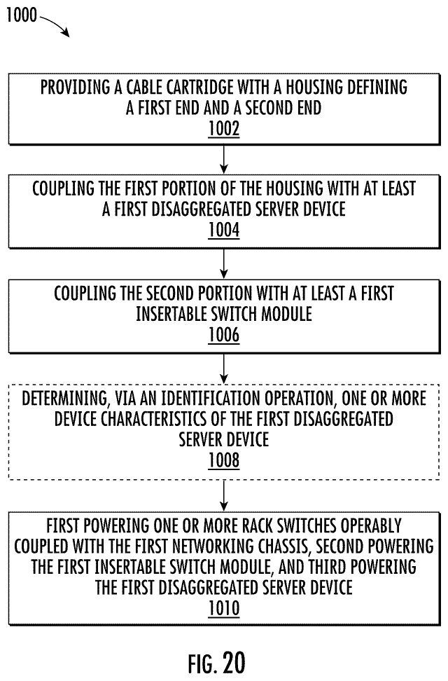

With reference to FIG. 20, an example method for network sequencing/initialization 100 is illustrated. As shown in operation 1002, the method 1000 may include providing a cable cartridge 800 with a housing 801 defining a first end 802 and a second end 804. The cable cartridge 800 may be configured for use with the networking chassis 105, 107 and associated datacenter rack 101 described herein. Although the identification and power sequencing operations described hereinafter reference to example cable cartridge 800, the present disclosure contemplates that these operations of method 1000 may occur in the absence of the cable cartridge 800. Said differently, the cable cartridge 800 provides an example mechanism and structure for operable coupling the disaggregated server devices 102 and the insertable switch modules 103, but the present disclosure contemplate that other mechanisms, techniques, etc. may be used.

Thereafter as shown in operations 1004 and 1006, the method may include coupling the first portion 802 of the housing 801 with at least a first disaggregated server device 102 supported by a networking chassis 105, 107. As described above, the first portion 802 of the cable cartridge 800 may be configured to physically interface with the connector 109 of the example disaggregated server devices 102 described herein. The method may further include coupling the second portion 804 of the housing 801 with at least a first insertable switch module 103 supported by the networking chassis 105, 107. By way of continued example, the second portion 804 of the cable cartridge 800 may be configured to physically interface with the connector 701 of the example insertable switch modules 103 described herein. In doing so, the cable cartridge may operate to operably couple an example first disaggregated server device 102 and an example first insertable switch module 103. The present disclosure contemplates that the configuration and dimensions (e.g., size and shape) of the housing 801 may vary based on the configuration of the networking chassis 105, 107, the disaggregated server devices 102, and/or the insertable switch module 103. In some embodiments, the cable cartridge 800 may be configured to operably couple each of the disaggregated server devices 102 and the insertable switch modules 103 of the example networking chassis 105, 107.

In some embodiments, as shown in operation 1008, the method 1000 may include determining, via an identification operation, one or more device characteristics of the first disaggregated server 102. The identification operation may operate as a Field Replaceable Unit (FRU) Electrically Erasable Programmable Read-Only Memory (EEPROM) operation in which the device characteristics (e.g., product name, part number, serial number, etc.) associated with the particular disaggregated server device 102 coupled with the cable cartridge 800 are identified. Given the modularity of the embodiments described herein, the identification operations of operation 1008 may operate to improve upon conventional solutions in which the identification of particular CPUs 202 and/or GPUs 208 was impractical or unnecessary due to the density of components on a particular node.

The method 1000 may further include a power sequencing operation shown in operation 1010. As shown, the method 100 may include first powering one or more rack switches 106 operably coupled with the first networking chassis 105, second powering the first insertable switch module 103; and third powering the first disaggregated server device 1012. Unlike conventional solutions in which the order in which components are initiated may be irrelevant, such as due to the inclusion of communication hardware alongside computing hardware on a common server, in some embodiments, the correct initiation of the components forming the network architecture 100 may be required for successful operation.

### Example Configurations

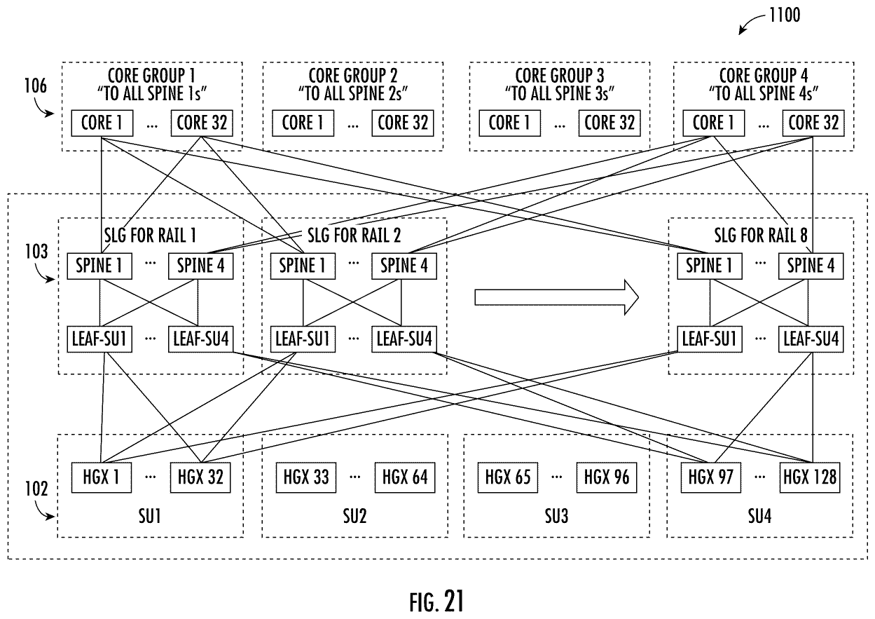

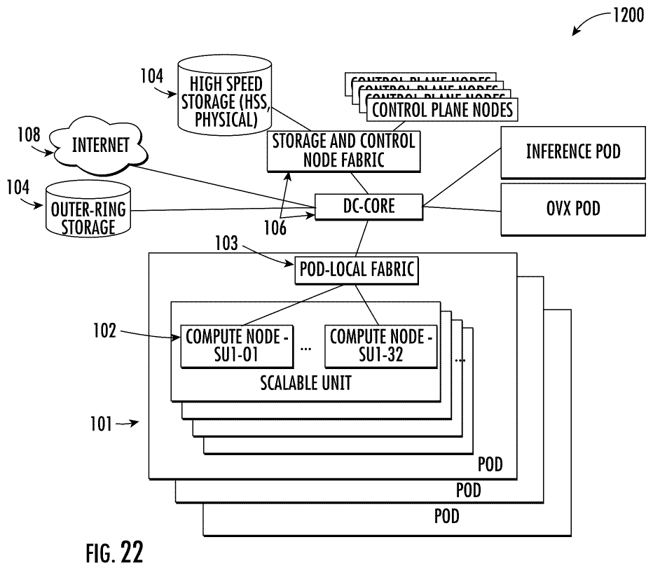

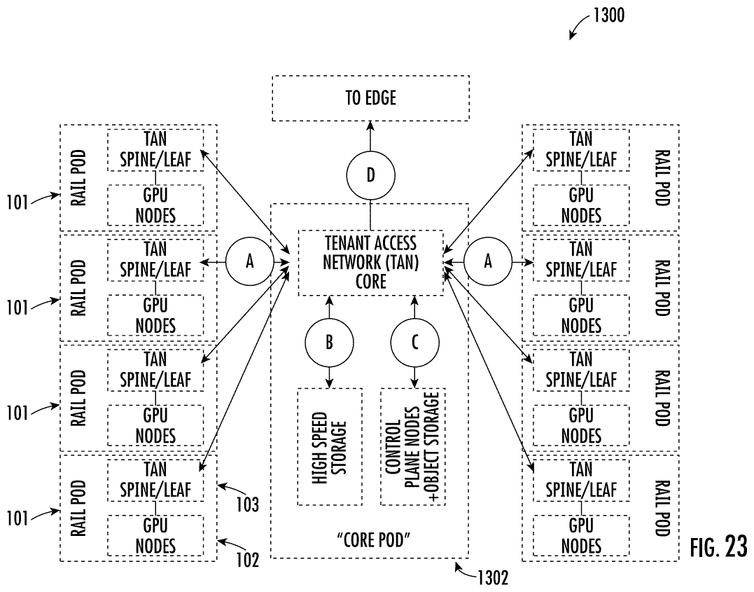

With reference to FIGS. 21-23, various network configuration 1100, 1200, and 1300 are illustrated for implementing one or more of the various disaggregated server devices 102 and/or insertable switch modules 103. As shown in FIG. 21, the configuration 1100 may operate as a three (3) layer computer fabric with a 1K rail POD. The disaggregated server devices 102, the insertable switch modules 103, and the rack switches 106 as described above are illustrated. As shown in FIG. 22, a logical architecture 1200 for storage an in-band fabric is shown. The configuration 1200 may employs a high-performance ethernet network fabric that is improves to maximum bandwidth. The I/O per-node for the HGX-based training compute nodes of 1200 may reach 40 GB/s (best bin). As shown in FIG. 23, the configuration 1300 may include a core pod 1302 that facilitates that scale out of storage.

Many modifications and other embodiments of the present disclosure will come to mind to one skilled in the art to which these embodiments pertain having the benefit of the teachings presented in the foregoing descriptions and the associated drawings. Although the figures only show certain components of the methods and systems described herein, it is understood that various other components may also be part of the disclosures herein. In addition, the method described above may include fewer steps in some cases, while in other cases may include additional steps. Modifications to the steps of the method described above, in some cases, may be performed in any order and in any combination.

Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

1. A networking chassis comprising:
a first disaggregated server device supported by the networking chassis, the first disaggregated server device comprising:
a first central processing unit (CPU);
a first graphics processing unit (GPU) coupled with the first CPU, wherein the first CPU and the first GPU are configured to perform one or more computing operations associated with the networking chassis; and
a first insertable switch module communicably coupled with the first disaggregated server device comprising:
one or more first switching chipsets; and
a first fabric management controller operably coupled with the one or more first switching chipsets, wherein the first insertable switch module is configured to at least partially control data transmission associated with the first disaggregated server device.

2. The networking chassis according to claim 1, wherein the first GPU of the first disaggregated server device is isolated on the first disaggregated server device.

3. The networking chassis according to claim 1, wherein the first GPU is the only GPU on the first disaggregated server device.

4. The networking chassis according to claim 1, wherein the first GPU is supported on the first disaggregated server device in the absence of other GPUs on the first disaggregated server device.

5. The networking chassis according to claim 1, wherein the first disaggregated server device further comprises one or more first thermal management components.

6. The networking chassis according to claim 5, wherein the one or more first thermal management components are configured to independently dissipate heat generated by the first CPU and/or the first GPU.

7. The networking chassis according to claim 5, wherein the one or more first thermal management components comprise one or more fans configured to dissipate heat generated by the first CPU and/or the first GPU.

8. The networking chassis according to claim 1, wherein the first insertable switch module further comprises one or more first switch thermal management components.

9. The networking chassis according to claim 8, wherein the one or more first switch thermal management components are configured to independently dissipate heat generated by the one or more first switching chipsets and/or the first fabric management controller.

10. The networking chassis according to claim 8, wherein the one or more first thermal management components comprise one or more fans configured to dissipate heat generated by the one or more first switching chipsets and/or the first fabric management controller.

11. The networking chassis according to claim 1, wherein the first disaggregated server device and/or the first insertable switch module are removably attached with the networking chassis.

12. The networking chassis according to claim 1, further comprising one or more power supply units (PSUs) configured to provide a direct current (DC) power input to the first disaggregated server device and/or the first insertable switch module.

13. The networking chassis according to claim 1, further comprising a second disaggregated server device comprising:
a second central processing unit (CPU);
a second graphics processing unit (GPU) coupled with the second CPU, wherein the second CPU and second GPU are configured to perform the one or more computing operations associated with the networking chassis.

14. The networking chassis according to claim 13, wherein the second GPU of the second disaggregated server device is isolated on the second disaggregated server device.

15. The networking chassis according to claim 13, wherein the second GPU is the only GPU on the second disaggregated server device.

16. The networking chassis according to claim 13, wherein the second GPU is supported on the second disaggregated server device in the absence of other GPUs on the second disaggregated server device.

17. The networking chassis according to claim 13, wherein the first GPU of the first disaggregated server device and the second GPU of the second disaggregated server device are communicably coupled via the first insertable switch module.

18. The networking chassis according to claim 13, wherein the first disaggregated server device and the second disaggregated server device are removably attached with the networking chassis.

19. The networking chassis according to claim 13, wherein operation of the second disaggregated server device is unimpacted by the removal of the first disaggregated server device.

20. The networking chassis according to claim 1, further comprising:
a plurality of disaggregated server devices comprising the first disaggregated server device; and
a plurality of insertable switch modules comprising the first insertable switch module.

21. The networking device according to claim 20, wherein each of the plurality of disaggregated server devices and the plurality of insertable switch module are physically supported by the networking chassis.
